(19) United States
(12) Patent Application Publication
(10) Pub. No.: US 2025/0393422 A1
(43) Pub. Date: Dec. 25, 2025

(54) DISPLAY DEVICE, ELECTRONIC DEVICE INCLUDING THE SAME AND METHOD FOR MANUFACTURING THE DISPLAY DEVICE

(71) Applicant: Samsung Display Co., Ltd., Yongin-si (KR)

(72) Inventors: YOUNGMIN AHN, Yongin-si (KR); HANBUM KWON, Yongin-si (KR); EUNBYUL KIM, Yongin-si (KR)

(21) Appl. No.: 19/092,915

(22) Filed: Mar. 27, 2025

(30) Foreign Application Priority Data
Jun. 21, 2024 (KR) 10-2024-0080873

(51) Int. Cl. H10K 59/131; H10K 59/12

(52) U.S. Cl. CPC H10K 59/131; H10K 59/1201

(57) ABSTRACT

A display device includes: a display panel comprising a display area having a pixel, and a non-display area, on which a plurality of pad electrodes are located; and a driver on the display panel and comprising a plurality of bump electrodes, each of which is arranged to correspond to respective ones of each of the plurality pad electrodes, wherein the plurality of pad electrodes include: a first conductive pattern comprising a conductive material; an auxiliary pattern protruding toward the bump electrodes and comprising an insulating material; and a second conductive pattern comprising a conductive material, wherein the auxiliary pattern includes: a first auxiliary pattern on at least a portion of the first conductive pattern; and a second auxiliary pattern that does not overlap the first conductive pattern in a plan view, wherein the second conductive pattern covers at least a portion of an upper portion of the first auxiliary pattern.

### CROSS-REFERENCE TO RELATED APPLICATION

The present application claims priority to and the benefit of Korean Patent Application No. 10-2024-0080873, filed on Jun. 21, 2024, in the Korean Intellectual Property Office, the entire disclosure of which is incorporated herein by reference.

### BACKGROUND

Aspects of some embodiments of the present disclosure herein relate to a display device, an electronic device and a method for manufacturing the same.

Electronic equipment for displaying images to users such as smartphones, digital cameras, laptop computers, navigations, and smart televisions include a display device for displaying images. The display device generates images to provide the images to users through a display screen.

Such a display device includes a display panel on which images are displayed. The display panel includes a plurality of gate lines, a plurality of data lines, and a plurality of pixels connected to the plurality of gate lines and the plurality of data lines.

The display panel may be connected to a driver that provides an electrical signal required for displaying images to the gate lines or the data lines.

The above information disclosed in this Background section is only for enhancement of understanding of the background and therefore the information discussed in this Background section does not necessarily constitute prior art.

### SUMMARY

Aspects of some embodiments of the present disclosure herein relate to a display device, an electronic device and a method for manufacturing the same, and for example, to a display device and an electronic device including a pad electrode and a bump electrode.

Aspects of some embodiments of the present disclosure include a display device having relatively improved electrical connection characteristics between a pad electrode and a bump electrode.

Aspects of some embodiments of the present disclosure also include a method for manufacturing a display device with a relatively simplified process.

According to some embodiments of the present disclosure, a display device includes: a display panel including a display area, on which a pixel is located, and a non-display area, on which a plurality of pad electrodes are located; and a driver on the display panel and including a plurality of bump electrodes, each of which corresponds to respective ones of each of the plurality pad electrodes. According to some embodiments, the plurality of pad electrodes may include a first conductive pattern including a conductive material, an auxiliary pattern protruding toward the bump electrode and including an insulating material, and a second conductive pattern comprising a conductive material. According to some embodiments, the auxiliary pattern may include a first auxiliary pattern on at least a portion of the first conductive pattern, and a second auxiliary pattern that does not overlap the first conductive pattern on a plane. According to some embodiments, the second conductive pattern may be configured to cover at least a portion of an upper portion of the first auxiliary pattern.

According to some embodiments, the first auxiliary pattern may include a plurality of unit auxiliary patterns on at least a portion of the first conductive pattern. According to some embodiments, the second auxiliary pattern may include a plurality of second unit auxiliary patterns that do not overlap the first conductive pattern.

According to some embodiments, the plurality of first unit auxiliary patterns may include a first sub-unit auxiliary pattern that entirely overlaps the first conductive pattern on the plane.

According to some embodiments, the plurality of first unit auxiliary patterns may include a second sub-unit auxiliary pattern of which a portion overlaps the first conductive pattern on the plane, and a remaining portion may not overlap the first conductive pattern.

According to some embodiments, the second conductive pattern may be provided in plurality. According to some embodiments, the plurality of second conductive patterns may extend in a first direction and be spaced apart from each other in a second direction crossing the first direction. According to some embodiments, each of the plurality of first unit auxiliary patterns and the plurality of second unit auxiliary patterns may be arranged side by side in the first direction and the second direction.

According to some embodiments, the second conductive pattern may be provided in plurality. According to some embodiments, the plurality of second conductive patterns may extend in a first direction and be spaced apart from each other in a second direction crossing the first direction. According to some embodiments, each of the plurality of first unit auxiliary patterns and the plurality of second unit auxiliary patterns may be arranged to be shifted by a predetermined distance in at least one of the first direction or the second direction.

According to some embodiments, the plurality of bump electrodes may be in contact with the second conductive pattern.

According to some embodiments, the display panel may further include a plurality of signal lines that are electrically connected to at least a portion of each of the plurality of pad electrodes. According to some embodiments, at least a portion of the plurality of signal lines may be in contact with the first conductive pattern.

According to some embodiments, the auxiliary pattern may include a polymer material.

According to some embodiments, the second conductive pattern may be provided in plurality. According to some embodiments, the plurality of second conductive patterns may extend in a first direction and be spaced apart from each other in a second direction crossing the first direction. According to some embodiments, a spaced portion may be provided between the plurality of second conductive patterns.

According to some embodiments, the second auxiliary pattern may include a (2-a)-th auxiliary pattern at the spaced portion.

According to some embodiments, the second auxiliary pattern may include a (2-b)-th auxiliary pattern that does not overlap the spaced portion.

According to some embodiments, the display panel may further include an insulating pattern below the first conductive pattern. According to some embodiments, the second auxiliary pattern may not overlap the insulating pattern on the plane.

According to some embodiments, a portion of the second conductive pattern may be in contact with the first conductive pattern.

According to some embodiments, the second conductive pattern may be directly located on at least a portion of an upper portion of the first auxiliary pattern.

According to some embodiments, the display device may further include a first adhesion layer between the display panel and the driver. According to some embodiments, the first adhesion layer may include a non-conductive film.

According to some embodiments, the pixel may include: a light emitting element; a transistor electrically connected to the light emitting element and comprising a semiconductor pattern and a gate overlapping the semiconductor pattern; and a plurality of conductive layers electrically connected to the transistor and on different layers on the transistor. According to some embodiments, each of the first conductive pattern and the second conductive pattern may include the same material as at least one of the plurality of conductive layers.

According to some embodiments of the present disclosure, a method for manufacturing a display device, the method includes: forming a display panel comprising a display area, on which a pixel is located, and a non-display area, on which a plurality of pad electrodes are located; providing a driver comprising a plurality of bump electrodes arranged to respectively correspond to the plurality of pad electrodes on the display panel; and interposing and pressing a first adhesion layer between the display panel and the driver to bond the plurality of pad electrodes to the plurality of bump electrodes. According to some embodiments, the forming of the display panel may include forming the plurality of pad electrodes on the non-display area. According to some embodiments, the forming of the plurality of pad electrodes may include: providing a conductive material to the non-display area to form a first conductive pattern; forming an auxiliary pattern to at least partially overlap the first conductive pattern; and providing a conductive material to cover at least a portion of the auxiliary pattern, thereby forming a second conductive pattern. According to some embodiments, the forming of the auxiliary pattern may be performed through a printing process.

According to some embodiments, the forming of the auxiliary pattern may include: forming a first auxiliary pattern located on at least a portion of the first conductive pattern; and forming a second auxiliary pattern that does not overlap the first conductive pattern on a plane.

According to some embodiments, the forming of the first auxiliary pattern may include forming a plurality of first unit auxiliary patterns of which at least a portion is located on the first conductive pattern.

According to some embodiments, the forming of the second auxiliary pattern may include forming a plurality of second unit auxiliary patterns that do not overlap the first conductive pattern.

According to some embodiments of the present disclosure, an electronic device includes: a display panel including a display area, on which a pixel is located, and a non-display area, on which a plurality of pad electrodes are located; a driver located on the display panel and including a plurality of bump electrodes, each of which is arranged to correspond to each of the plurality pad electrodes; and a housing accommodate the display panel. According to some embodiments, the plurality of pad electrodes may include a first conductive pattern including a conductive material, an auxiliary pattern protruding toward the bump electrode and including an insulating material, and a second conductive pattern comprising a conductive material.

According to some embodiments, the auxiliary pattern may include a first auxiliary pattern on at least a portion of the first conductive pattern, and a second auxiliary pattern that does not overlap the first conductive pattern on a plane. According to some embodiments, the second conductive pattern may be configured to cover at least a portion of an upper portion of the first auxiliary pattern.

### BRIEF DESCRIPTION OF THE DRAWINGS

The accompanying drawings are included to provide a further understanding of aspects of embodiments according to the present disclosure, and are incorporated in and constitute a part of this specification. The drawings illustrate aspects of embodiments of the present disclosure and, together with the description, serve to explain principles of embodiments according to the present disclosure. In the drawings:

FIG. 1 is a perspective view of an electronic apparatus according to some embodiments of the present disclosure;

FIG. 2 is an exploded perspective view of the electronic apparatus according to some embodiments of the present disclosure;

FIG. 3 is a cross-sectional view of a display device according to some embodiments of the present disclosure;

FIG. 4 is a plan view of a display panel according to some embodiments of the present disclosure;

FIG. 5 is a cross-sectional view of a pixel according to some embodiments of the present disclosure;

FIG. 6 is a side view of the display device according to some embodiments of the present disclosure;

FIG. 7 is an enlarged perspective view illustrating a portion of the display device according to some embodiments of the present disclosure;

FIG. 8 is an enlarged plan view illustrating a portion of first pad electrodes according to some embodiments of the present disclosure;

FIGS. 9A and 9B are cross-sectional views illustrating a portion of the display panel according to some embodiments of the present disclosure;

FIG. 10 is a cross-sectional view illustrating a portion of the display device according to some embodiments of the present disclosure;

FIGS. 11A and 11B are enlarged plan views illustrating a portion of the first pad electrodes according to some embodiments of the present disclosure;

FIGS. 12A and 12B are enlarged plan views of a first pad area according to some embodiments of the present disclosure;

FIG. 13A is a flowchart illustrating a method for manufacturing a display device according to some embodiments of the present disclosure;

FIG. 13B is a flowchart illustrating some processes in the method for manufacturing the display device according to some embodiments of the present disclosure;

FIGS. 14A to 14C are cross-sectional views illustrating some processes in the method for manufacturing the display device according to some embodiments of the present disclosure; and

FIG. 15 is a cross-sectional view illustrating some processes in the method for manufacturing the display device according to some embodiments of the present disclosure.

### DETAILED DESCRIPTION

In this specification, it will also be understood that when one component (or region, layer, portion, etc.) is referred to as being ‘on’, ‘connected to’, or ‘coupled to’ another component, it can be directly connected/coupled on/to the one component, or an intervening third component may also be present.

Like reference numerals refer to like elements throughout. Also, in the figures, the thickness, ratio, and dimensions of components are exaggerated for clarity of illustration. The term “and/or” includes any and all combinations of one or more of the associated listed items.

It will be understood that although the terms such as ‘first’ and ‘second’ are used herein to describe various elements, these elements should not be limited by these terms. The terms are only used to distinguish one component from other components. For example, a first element referred to as a first element in some embodiments can be referred to as a second element in other embodiments without departing from the scope of the appended claims. The terms of a singular form may include plural forms unless referred to the contrary.

Also, “under”, “below”, “above”, “upper”, and the like are used for explaining relation association of components illustrated in the drawings. The terms may be a relative concept and described based on directions expressed in the drawings.

The meaning of “include” or “comprise” specifies a property, a fixed number, a step, an operation, an element, a component or a combination thereof, but does not exclude other properties, fixed numbers, steps, operations, elements, components or combinations thereof.

In this specification, “directly located” or “directly arranged” may mean that there is no layer, film, region, plate, or the like between a portion of the layer, the layer, the region, the plate, or the like and the other portion. For example, “directly located” may mean being located without using an additional member such and an adhesion member between two layers or two members.

Unless otherwise defined, all terms (including technical and scientific terms) used herein have the same meaning as commonly understood by a person of ordinary skill in the art to which this invention belongs. In addition, terms such as those defined in commonly used dictionaries should be interpreted as having meanings consistent with their meanings in the context of the relevant technology, and unless explicitly defined, it should not be interpreted in an overly idealistic or overly formal sense.

Hereinafter, aspects of some embodiments of the present disclosure will be described in more detail with reference to the accompanying drawings.

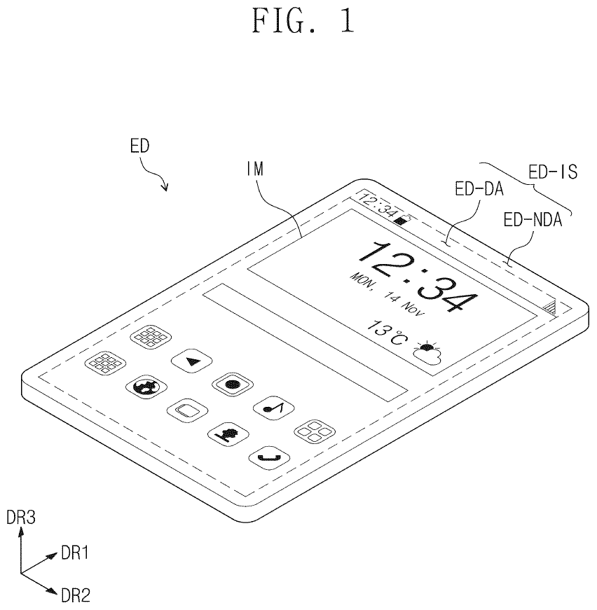

FIG. 1 is a perspective view of an electronic apparatus according to some embodiments of the present disclosure.

Referring to FIG. 1, an electronic apparatus ED may have a rectangular shape having short sides extending in a first direction DR1 and long sides extending in a second direction DR2 crossing the first direction DR1. However, embodiments according to the present disclosure are not limited thereto, and the electronic apparatus ED may have various shapes such as circular, polygonal, or irregular shapes.

Hereinafter, a direction perpendicularly crossing (e.g., perpendicular or normal with respect to) a plane defined by the first direction DR1 and the second direction DR2 may be defined as a third direction DR3. In addition, in this specification the phrases “when viewed on the plane” or “in a plan view” may be defined in a state when viewed from the third direction DR3 (e.g., toward a display surface of the electronic apparatus ED).

A top surface of the electronic apparatus ED may be defined as a display surface ED-IS, and the display surface ED-IS may have a plane defined by the first direction DR1 and the second direction DR2. Images IM generated in the electronic apparatus ED may be provided to a user through the display surface ED-IS.

The display surface ED-IS may include a display area ED-DA and a non-display area ED-NDA surrounding (e.g., in a periphery or outside a footprint of) the display area ED-DA. The display area ED-DA may display an image, and the non-display area ED-NDA may not display an image. The non-display area ED-NDA may surround the display area ED-DA and define an edge of the electronic apparatus ED that is printed in a color (e.g., a set or predetermined color).

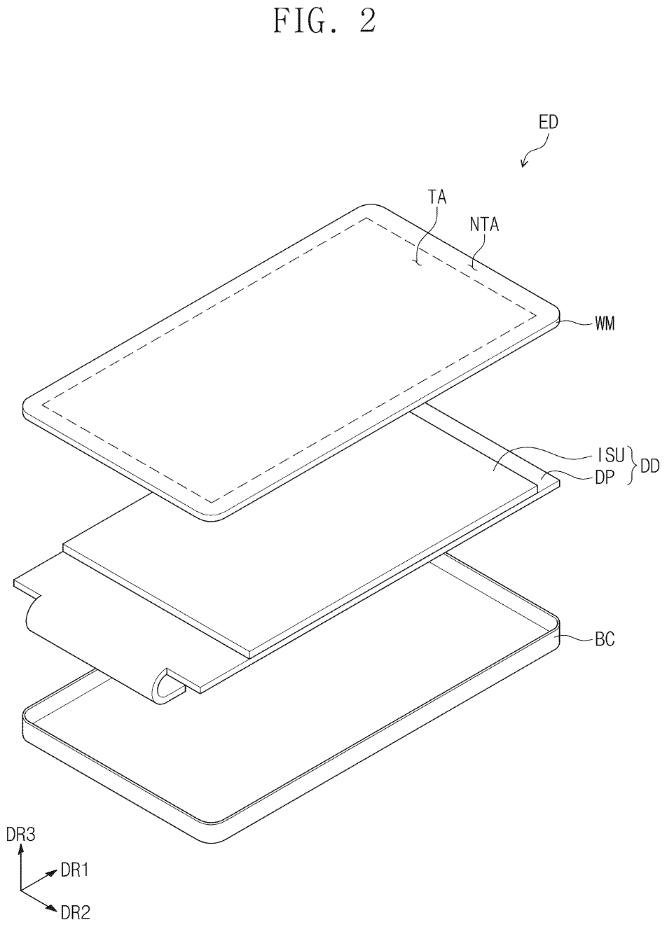

FIG. 2 is an exploded perspective view of the electronic apparatus according to some embodiments of the present disclosure.

Referring to FIG. 2, the electronic apparatus ED may include a window WM, a display device DD, and a housing BC. The housing BC may accommodate the display device DD and be coupled to the window WM. According to some embodiments, the electronic apparatus ED may further include other electronic modules accommodated in the housing BC and electrically connected to the display panel DP. For example, the electronic apparatus ED may further include a main board, a circuit module mounted on the main board, a camera module, a power module, etc.

The window WM may be located above the display device DD. The window WM may transmit images provided from the display device DD to the outside. The window WM may include a transmission area TA and a non-transmission area NTA. The transmission area TA may overlap the display area ED-DA of FIG. 1. The transparent area TA may have a shape corresponding to the display area ED-DA.

The non-transparent area NTA may overlap the non-display area ED-NDA (see FIG. 1) and may have a shape corresponding to the non-display area ED-NDA (see FIG. 1). The non-transmission area NTA may be an area having a light transmittance that is relatively less than that of the transmission area TA. The display device DD may generate images and detect an external input.

The display device DD may include a display panel DP and an input sensor ISU. According to some embodiments, the display device DD may further include an anti-reflection member located on the input sensor ISU. The anti-reflection material may include a polarizer and a retarder or may include a color filter and a black matrix.

The display panel DP may be an emission-type display panel, and the embodiments of the present disclosure are not limited to kinds of display panels. For example, the display panel DP may be an organic light emitting display panel or an inorganic light emitting display panel. An emission layer of the organic light emitting display panel may include an organic light emitting material. The emission layer of the inorganic light emitting display panel may include quantum dots, quantum rods, nano LEDs, etc. Hereinafter, the organic light emitting display panel will be described as an example of the display panel DP.

The input sensor ISU may include any one of a capacitive sensor, an optical sensor, an ultrasonic sensor, and an electromagnetic induction sensor. The input sensor ISU may be provided on the display panel DP through a continuous process or may be manufactured separately and then attached to an upper side of the display panel DP through an adhesion layer.

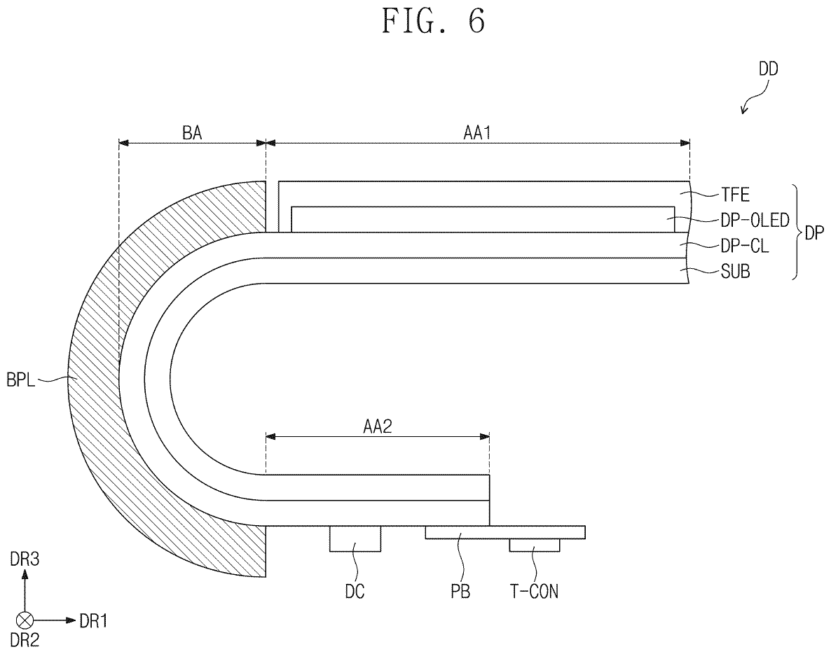

In the display device DD according to some embodiments, a portion of the display panel DP may be bent so that a driver DC (see FIG. 6) faces downward. The non-display area ED-NDA (see FIG. 1) of the display panel DP may be bent. However, the bent portion is not limited thereto, and the circuit board PB (see FIG. 6) may be bent without bending the display panel DP.

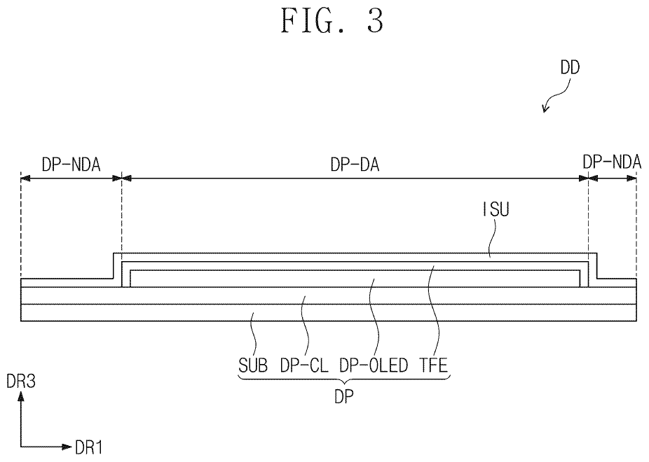

FIG. 3 is a cross-sectional view of the display device according to some embodiments of the present disclosure.

Referring to FIG. 3, the display panel DP may include a substrate SUB, a circuit element layer DP-CL located on the substrate SUB, a display element layer DP-OLED, and a thin film encapsulation layer TFE. The input sensor ISU may be located on the thin film encapsulation layer TFE.

The substrate SUB may include a display area DP-DA and a non-display area DP-NDA around the display area DP-DA. The substrate SUB may include glass or a flexible plastic material such as polyimide (PI). The display element layer DP-OLED may be located on the display area DP-DA.

A plurality of pixels may be located on the circuit element layer DP-CL and the display element layer DP-OLED. According to some embodiments, each of the pixels may include a plurality of transistors and at least one capacitor, which are located on the circuit element layer DP-CL, and a light emitting element located on the display element layer DP-OLED and connected to the transistors.

The thin film encapsulation layer TFE may be located on the circuit element layer DP-CL to cover the display element layer DP-OLED. The thin film encapsulation layer TFE may protect the pixels from moisture, oxygen, and external foreign substances or contaminants.

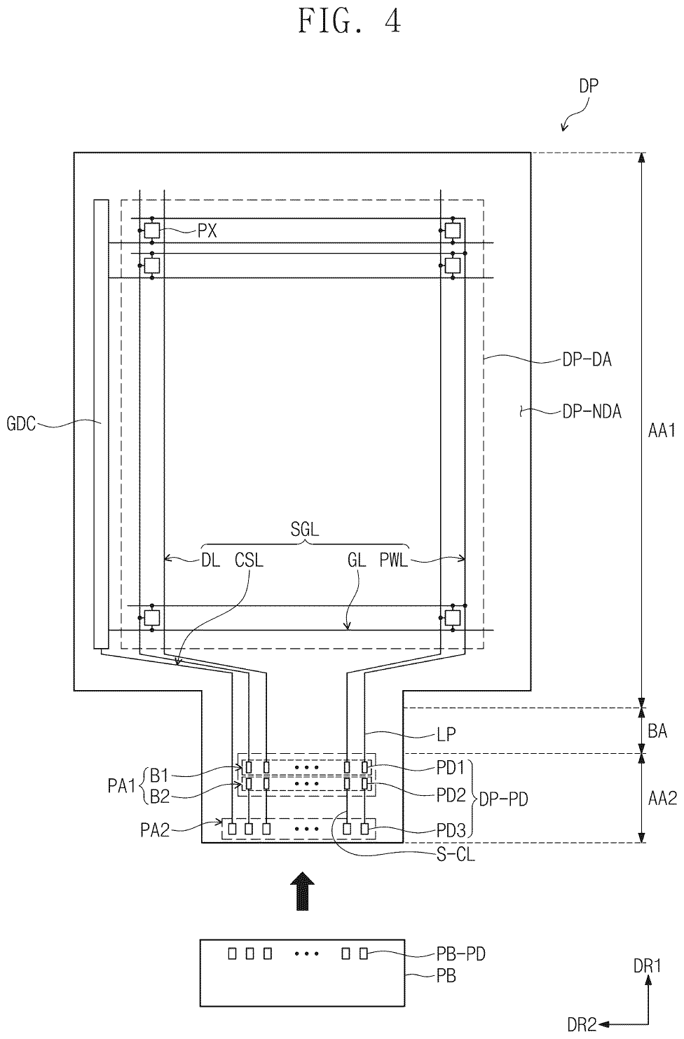

FIG. 4 is a plan view of the display panel according to some embodiments of the present disclosure. FIG. 4 illustrates a planar shape of the display panel DP illustrated in FIG. 3.

Referring to FIG. 4, the display panel DP may include a plurality of pixels PX, a gate driving circuit GDC, a plurality of signal lines SGL, and a plurality of pad electrodes DP-PD.

The display panel DP may include a first portion AA1, a second portion AA2, and a bent portion BA located between the first portion AA1 and the second portion AA2. The first portion AA1, the bent portion BA, and the second portion AA2 may be sequentially arranged along the second direction DR2. The bent portion BA may extend in the second direction DR2 from the first portion AA1, and the second portion AA2 may extend in the second direction DR2 from the bent portion BA.

The first portion AA1 may have long sides extending in the second direction DR2 and be spaced apart from each other in the first direction DR1. A width of each of the bent portion BA and the second portion AA2 may be less than that of the first portion AA1 with respect to the first direction DR1.

The pixels PX may be located on the display area DP-DA. Each of the pixels PX may include an organic light emitting diode and a pixel driving circuit connected to the organic light emitting diode. The gate driving circuit GDC may sequentially output gate signals to a plurality of gate lines GL to be described in more detail later. The transistors of the gate driving circuit GDC may be formed through the same process as the transistors of the pixel PX such as a low temperature polycrystalline silicon (LTPS) process or a low temperature polycrystalline oxide (LTPO) process. The display panel DP may further include another driving circuit that provides emission control signals to the pixels PX.

The signal lines SGL may include gate lines GL, data lines DL, power lines PWL, and control signal lines CSL. The gate lines GL may be respectively connected to corresponding pixels of the pixels PX, and the data lines DL may be respectively connected to corresponding pixels PX of the pixels PX. The power line PWL may be connected to the pixels PX. The control signal line CSL may provide control signals to the scan driving circuit.

The signal lines SGL may overlap the display area DP-DA and the non-display area DP-NDA. Each of the signal lines SGL may include a line part LP. The line part LP may overlap the display area DP-DA and the non-display area DP-NDA.

The plurality of pad electrodes DP-PD may be located on the second portion AA2 of the non-display area DP-NDA. The plurality of pad electrodes DP-PD may include first pad electrodes PD1, second pad electrodes PD2, and substrate-side pad electrodes PD-P. An area on which the first and second pad electrodes PD1 and PD2 are located may be defined as a first pad area PA1, and an area on which the substrate-side pad electrodes PD-P are located may be defined as a second pad area PA2.

The first pad area PA1 may be an area overlapping the driver DC (see FIG. 6), and the second pad area PA2 may be an area overlapping the circuit board PB.

The first pad area PA1 may include a first area B1 on which the first pad electrodes PD1 are located and a second area B2 on which the second pad electrodes PD2 are located. The first pad area PA1 and the second pad area PA2 may be located within the non-display area DP-NDA. The first pad area PA1 and the second pad area PA2 may be spaced apart from each other in the second direction DR2. The first pad area PA1 may be an area adjacent to the display area DP-DA compared to the second pad area PA2, and the second pad area PA2 may be an area spaced apart from the display area DP-DA with the first pad area PA1 therebetween.

Each of the first pad electrodes PD1 may be connected to a corresponding data line DL of the data lines DL. According to some embodiments, the first pad electrodes PD1 and the second pad electrodes PD2 may be electrically connected to each other. The second pad electrodes PD2 may be connected to the substrate-side pad electrodes PD-P through connection signal lines S-CL.

The circuit board PB may include a plurality of circuit pads PB-PD. The circuit pads PB-PD may be arranged in the first direction DR1. The circuit pads PB-PD of the circuit board PB may be connected to and in contact with substrate-side pad electrodes PD-P of the second pad area PA2.

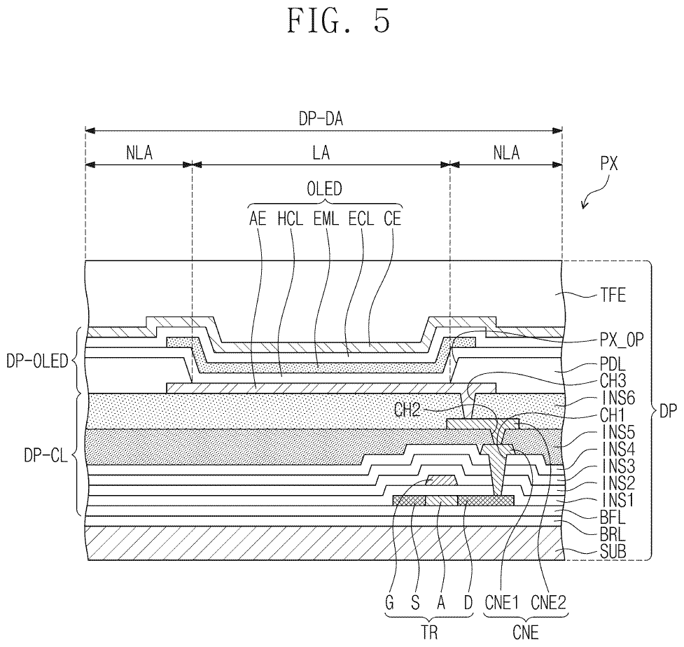

FIG. 5 is a cross-sectional view of the pixel according to some embodiments of the present disclosure.

Referring to FIGS. 4 and 5, the pixel PX may include a transistor TR and a light emitting element OLED. The light emitting element OLED may include a first electrode AE (or anode), a second electrode CE (or cathode), a hole control layer HCL, an electron control layer ECL, and an emission layer EML.

The transistor TR and the light emitting element OLED may be located on the substrate SUB. Although one transistor TR is illustrated as an example, in practice, the pixel PX may include a plurality of transistors and at least one capacitor for driving the light emitting element OLED. The plurality of transistors and at least one capacitor may be connected to each other.

The display area DP-DA may include an emission area LA corresponding to each pixel PX and a non-emission area NLA around the emission area LA. The light emitting element OLED may be located on the emission area LA.

The substrate SUB may include polyimide (PI) as a flexible plastic material. A barrier layer BRL may be located on the substrate SUB. A buffer layer BFL may be located on the barrier layer BRL. Each of the barrier layer BRL and the buffer layer BFL may be an inorganic layer.

A semiconductor pattern may be arranged on the buffer layer BFL. The semiconductor pattern may include polysilicon, amorphous silicon, or metal oxide. The semiconductor pattern may be doped with N-type dopants or P-type dopants. The semiconductor pattern may include a high-doped region and a low-doped region. The high-doped region may have conductivity greater than that of the low-doped region and may practically serve as source and drain electrodes of the transistor TR. The low-doped region may effectively correspond to an active (or channel) of the transistor.

A source S, an active A, and a drain D of the transistor TR may be provided from the semiconductor pattern. A first insulating layer INS1 may be arranged on the semiconductor pattern. A gate G of the transistor TR may be located on the first insulating layer INS1. A second insulating layer INS2 may be located on the gate G. A third insulating layer INS3 may be located on the second insulating layer INS2. A fourth insulating layer INS4 may be located on the third insulating layer INS3.

A connection electrode CNE may include a first connection electrode CNE1 and a second connection electrode CNE2 to connect the transistor TR and the light emitting element OLED. The first connection electrode CNE1 may be located on the fourth insulating layer INS4 and may be connected to the drain D through a first contact hole CH1 defined in the first to fourth insulating layers INS1 to INS4.

A fifth insulating layer INS5 may be located on the fourth insulating layer INS4. The second connection electrode CNE2 may be located on the fifth insulating layer INS5. The second connection electrode CNE2 may be connected to the first connection electrode CNE1 through a second contact hole CH2 defined in the fifth insulating layers INS5. The second connection electrode CNE2 may be the data line DL of FIG. 4.

A sixth insulating layer INS6 may be located on the second connection electrode CNE2. The layers from the buffer layer BFL to the sixth insulating layer INS6 may be defined as the circuit element layer DP-CL. Each of the first insulating layer INS1 to the sixth insulating layer INS6 may be an inorganic layer or an organic layer.

The first electrode AE may be located on the sixth insulating layer INS6. The first electrode AE may be connected to the second connection electrode CNE2 through the third contact hole CH3 defined in the sixth insulating layer INS6. The first electrode AE may be connected to the transistor TR via the first and second connection electrodes CNE1 and CNE2. A pixel defining layer PDL having an opening PX_OP defined therein to expose a portion (e.g., a set or predetermined portion) of the first electrode AE may be located on the first electrode AE and the sixth insulating layer INS6.

The hole control layer HCL may be located on the first electrode AE and the pixel defining layer PDL. The hole control layer HCL may include a hole transport layer and a hole injection layer.

The emission layer EML may be located on the hole control layer HCL. The emission layer EML may be located on an area corresponding to the opening OP. The emission layer EML may include organic and/or inorganic materials. The emission layer EML may emit one of red light, green light, and blue light.

The electron control layer ECL may be located on the emission layer EML and the hole control layer HCL. The electron control layer ECL may include an electron transport layer and an electron injection layer. The hole control layer HCL and the electron control layer ECL may be commonly arranged on the light emitting region LA and the non-emission region NLA.

The second electrode CE may be located on the electronic control layer ECL. The second electrode CE may be commonly arranged on the pixels PX. The layer on which the light emitting element OLED is located may be defined as the display element layer DP-OLED.

The thin film encapsulation layer TFE may be located on the second electrode CE to cover the pixel PX (see FIG. 4). According to some embodiments, the thin film encapsulation TFE layer may be provided as a plurality of layers. Some of the plurality of layers may include an inorganic insulating layer and protect the pixel PX (see FIG. 4) from moisture/oxygen. The remaining some layers may include organic insulating layers and protect the pixels PX (see FIG. 4) from foreign substances or contaminants such as dust particles.

A first voltage may be applied to the first electrode AE through the transistor TR, and a second voltage having a lower level than the first voltage may be applied to the second electrode CE. When holes and electrons injected into the emission layer EML are coupled to provide excitons, the light emitting element OLED may emit light when the excitons are transited to the ground state.

FIG. 6 is a side view of the display device according to some embodiments of the present disclosure. FIG. 6 is a view illustrating a state in which the bent portion BA is bent on the display panel DP of FIG. 4. FIG. 6 is a side view of the display device DD when viewed in the first direction DR1.

The substrate SUB, the circuit element layer DP-CL, the display element layer DP-OLED, and the thin film encapsulation layer TFE of FIG. 6 are identical to the substrate SUB, the circuit element layer DP-CL, the display element layer DP-OLED, and the thin film encapsulation layer TFE of FIG. 5, and thus, detailed descriptions will be omitted.

The display device DD may include a driver DC, a circuit board PB, a bending protection layer BPL, and a timing controller T-CON.

The driver DC may be located on the display panel DP and may be mounted on the display panel DP. However, embodiments according to the present disclosure are not limited thereto. For example, the driver DC may generate a driving signal that is required for an operation of the display panel DP based on a control signal transmitted from the circuit board PB.

The circuit board PB may be located on one end of the substrate SUB and may be electrically connected to the circuit element layer DP-CL. The timing controller T-CON may be located on the circuit board PB. The timing controller T-CON may be provided as a direct circuit chip and may be mounted on a top surface of the circuit board PB.

The bent portion BA may be bent so that the second portion AA2 is located below the first portion AA1. Thus, the driver DC, the circuit board PB, and the timing controller T-CON may be located below the second portion AA2.

A bending protection layer BPL may be located on the bent portion BA. A bending protection layer BPL may be adjacent to edges of the first and second portions AA1 and AA2. The bending protection layer BPL may be arranged to be spaced apart from the thin film encapsulation layer TFE in the second direction DR2. The bending protection layer BPL may be bent together with the bent portion BA when the display panel DP is bent.

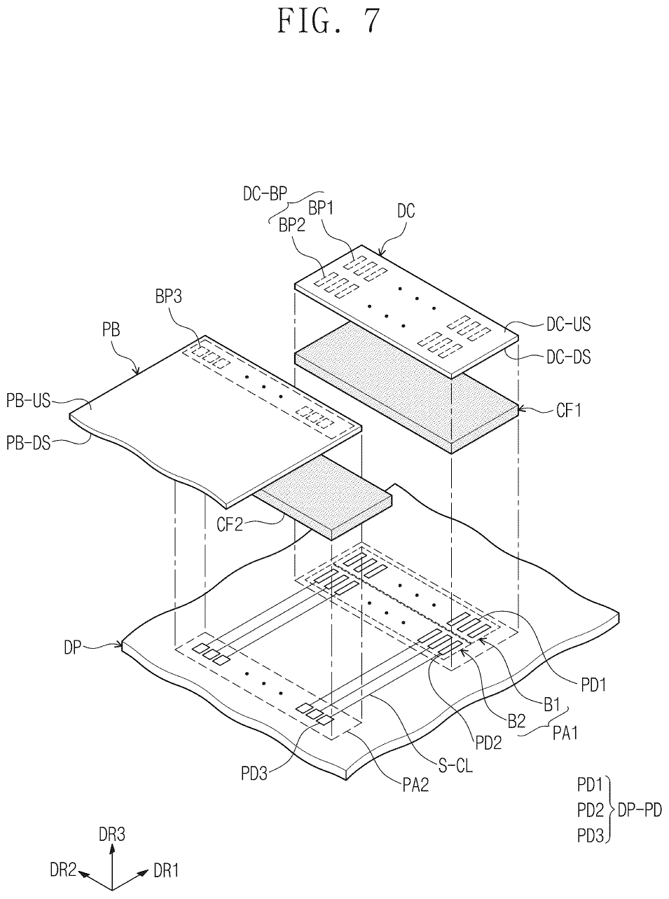

FIG. 7 is an enlarged perspective view illustrating a portion of the display device according to some embodiments of the present disclosure. In FIG. 7, the driver DC, the circuit board PB, and the display panel DP on the pad area PA illustrated in FIG. 4 are enlarged and illustrated. For example, the driver DC and circuit board PB in FIG. 7 are shown as being disassembled from the display panel DP.

Referring to FIGS. 4 and 7, the driver DC may be bonded to the first pad area PA1 through the first adhesion layer CF1. The circuit board PB may be bonded to the second pad area PA2 through a second adhesion layer CF2.

Each of the first and second adhesion layers CF1 and CF2 may include a synthetic resin having adhesive properties. Each of the first and second adhesion layers CF1 and CF2 may include a non-conductive film. Each of the first and second adhesion layers CF1 and CF2 may not include conductive particles such as conductive balls and may be made of a curable polymer material.

When the first adhesion layer CF1 is cured, the first and second pad electrodes PD1 and PD2 and the bump electrodes DC-BP may be fixed in a state of contact. When the second adhesion layer CF2 is cured, the substrate-side pad electrodes PD-P and the circuit pads PB-PD may be fixed in a state of contact.

The first pad area PA1 of the display panel DP may overlap the driver DC, and the second pad area PA2 may overlap the circuit board PB. The first pad area PA1 may include a first area B1 on which the first pad electrodes PD1 are located and a second area B2 on which the second pad electrodes PD2 are located. The first pad area PA1 and the second pad area PA2 may be located within the non-display area DP-NDA. The first pad area PA1 and the second pad area PA2 may be spaced apart from each other in the second direction DR2.

The driver DC may be located on the first and second pad electrodes PD1 and PD2. The driver DC may include a driver-integrated circuit DC-B, and the driver-integrated circuit DC-B may include a top surface DC-US and a bottom surface DC-DS.

The bottom surface DC-DS of the driver DC may be a surface facing the first and second pad electrodes PD1 and PD2. The driver DC may include bump electrodes DC-BP electrically connected to the first pad electrodes PD1 located on the substrate SUB. The bump electrodes DC-BP may be located on the bottom surface DC-DS of the driver-integrated circuit DC-B. The bottom surface DC-DS of the driver-integrated circuit DC-B may be a base surface on which the bump electrodes DC-BP are provided. The bump electrodes DC-BP may be arranged to correspond to respective ones of the pad electrodes PD1 and PD2.

The bump electrodes DC-BP may include first bump electrodes BP1 and second bump electrodes BP2. The first bump electrodes BP1 and the second bump electrodes BP2 may be spaced apart from each other in the second direction DR2. The first bump electrodes BP1 may be arranged in the first direction DR1. The second bump electrodes BP2 may be arranged in the first direction DR1. In FIG. 7, for convenience of explanation, a planar shape of each of the bump electrodes DC-BP may be illustrated with a dotted line on the top surface DC-US of the driver DC, but each of the first bump electrodes BP1 and the second bump electrodes BP2 may have a shape that protrudes from the bottom surface DC-DS of the driver DC and is exposed to the outside.

When the driver DC is bonded to the display panel DP by the first adhesion layer CF1, at least a portion of each of the first bump electrodes BP1 may be electrically connected by being in contact with the first pad electrodes PD1, and at least a portion of each of the second bump electrodes BP2 may be electrically connected by being in contact with the second pad electrodes PD2. The first bump electrodes BP1 may be arranged adjacent to the display area DP-DA (see FIG. 4) compared to the second bump electrodes BP2, and the second bump electrodes BP2 may be arranged to be spaced apart from the display area DP-DA (see FIG. 4) with the first bump electrodes BP1 therebetween.

The drive unit DC may include the driver-integrated circuit DC-B. The driver-integrated circuit DC-B may be located on the bump electrodes DC-BP. The driver-integrated circuit DC-B may be connected to the bump electrodes DC-BP. The driver DC may receive first signals from the outside through the second pad electrodes PD2 and the second bump electrodes BP2. The driver DC may provide second signals generated based on the signals to the first pad electrodes PD1 through the first bump electrodes BP1. The first signal may be a video signal, which is a digital signal applied from the outside, and the second signal may be a data signal, which is an analog signal. The driver DC may generate an analog voltage corresponding to a grayscale value of the image signal. A data signal may be provided to the pixel PX through the data line DL as illustrated in FIG. 4.

The circuit board PB may be located on the display panel DP. The circuit board PB may be located on the substrate-side pad electrodes PD-P. The circuit board PB may include a top surface PB-US and a bottom surface PB-DS. The bottom surface PB-DS of the circuit board PB may be a surface facing the substrate-side pad electrodes PD-P. The circuit board PB may include a plurality of circuit pads PB-PD electrically connected to substrate-side pad electrodes PD-P. The circuit pads PB-PD may be located on the top surface PB-US of the circuit board PB. The circuit pads PB-PD may be arranged in the second direction DR2. The circuit board PB may provide image signals, driving voltages, and other control signals to the driver DC.

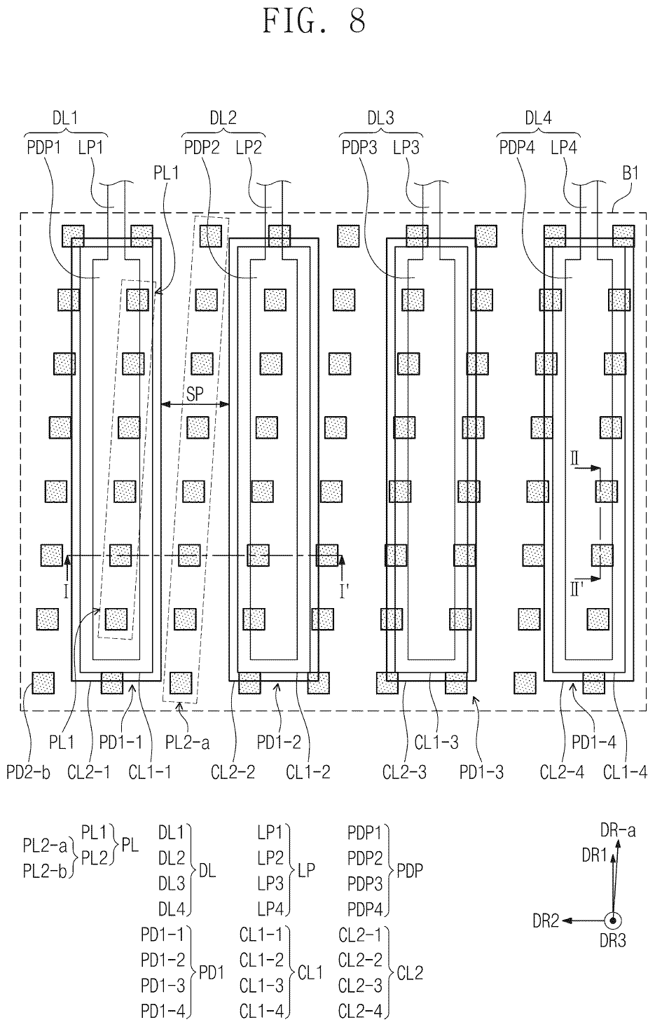

Hereinafter, the planar shape of each of the plurality of pad electrodes included in the display panel and the connection shape of the pad electrodes and bump electrodes will be described with reference to FIG. 8, etc.

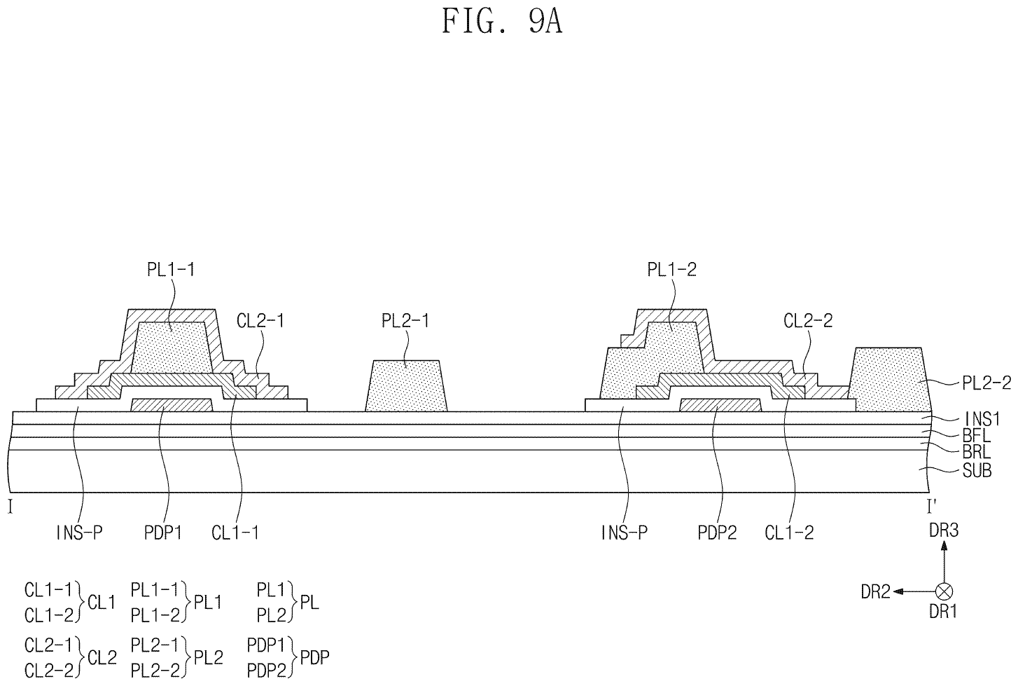

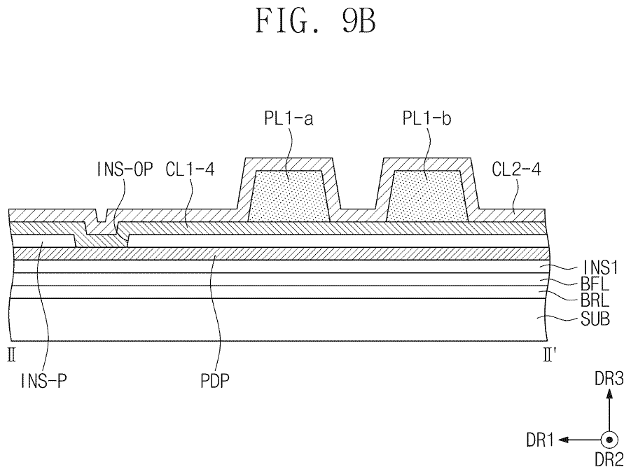

FIG. 8 is an enlarged plan view illustrating a portion of the first pad electrodes according to some embodiments of the present disclosure. FIGS. 9A and 9B are cross-sectional views illustrating a portion of the display panel according to some embodiments of the present disclosure. FIG. 9a illustrates a cross-section of a portion of the display panel corresponding to an I-I′ cutting line of FIG. 8, and FIG. 9b illustrates a cross-section of a portion of the display panel corresponding to an II-II′ cutting line of FIG. 8.

For example, in FIG. 8, the first pad electrode PD1 is illustrated as being located on the first area B1 of the first pad areas, but the second pad electrode PD2 and the third pad electrode (PD3) may have the same configuration as the first pad electrode PD1. In addition, although the data line DL is illustrated as an example in FIG. 8, embodiments according to the present disclosure are not limited thereto and may be other signal lines SGL illustrated in FIG. 4.

Referring to FIGS. 4, 8, 9A and 9B together, the data lines DL may include line parts LP and pad parts PDP. Each of the line parts LP may be connected to a corresponding pixel PX of the pixels PX. Each of the line parts LP may extend in the first direction DR1 and be connected to a corresponding pad electrode DP-PD of the pad electrodes DP-PD. Each of the line parts LP may be connected to a corresponding pad electrode of the first pad electrodes PD1. The data lines DL may be provided in plurality. The data lines DL may include first to fourth data lines DL1, DL2, DL3, and DL4. The first data line DL1 may include a first line part LP1 and a first pad part PDP1. The second data line DL2 may include a second line part LP2 and a second pad part PDP2. The third data line DL3 may include a third line part LP3 and a third pad part PDP3. The fourth data line DL4 may include a fourth line part LP4 and a fourth pad part PDP4.

The pad part PDP may extend in the first direction DR1 from an end of the line part LP. According to some embodiments, the pad part PDP and the line part LP of the data line DL may be located on different layers and connected to each other. A width of the pad part PDP in the second direction DR2 may be greater than a width of the line part LP.

In the display panel according to some embodiments, the first pad electrode PD1 may be located on the substrate SUB. The first pad electrode PD1 may include a first conductive pattern CL1 and a second conductive pattern CL2. When viewed on a plane, each of the first and second conductive patterns CL1 and CL2 may overlap the pad part PDP. For example, the first and second conductive patterns CL1 and CL2 are illustrated, but any one of the electrodes may be omitted, or additional electrodes may be located. Each of the first conductive pattern CL1 and the second conductive pattern CL2 may include a conductive material. Each of the first conductive pattern CL1 and the second conductive pattern CL2 may include a conductive metal.

The first pad electrode PD1 may be provided in plurality. The first pad electrode PD1 may include a (1-1)-th pad electrode PD1-1, a (1-2)-th pad electrode PD1-2, a (1-3)-th pad electrode PD1-3, and a (1-4)-th pad electrode PD1-4. The (1-1)-th pad electrode PD1-1, the (1-2)-th pad electrode PD1-2, the (1-3)-th pad electrode PD1-3, and the (1-4)-th pad electrode PD1-4 may extend in the first direction DR1 and may be spaced apart from each other in the second direction DR2.

Each of the (1-1)-th pad electrode PD1-1, the (1-2)-th pad electrode PD1-2, the (1-3)-th pad electrode PD1-3, and the (1-4)-th pad electrode PD1-4 may include a first conductive pattern CL1 and a second conductive pattern CL2. The (1-1)-th pad electrode PD1-1 may include a (1-1)-th conductive pattern CL1-1 and a (2-1)-th conductive pattern CL2-1. The (1-2)-th pad electrode PD1-2 may include a (1-2)-th conductive pattern CL1-2 and a (2-2)-th conductive pattern CL2-2. The (1-3)-th pad electrode PD1-3 may include a (1-3)-th conductive pattern CL1-3 and a (2-3)-th conductive pattern CL2-3. The (1-4)-th pad electrode PD1-4 may include a (1-4)-th conductive pattern CL1-4 and a (2-4)-th conductive pattern CL2-4.

Each of the (1-1)-th pad electrode PD1-1, the (1-2)-th pad electrode PD1-2, the (1-3)-th pad electrode PD1-3, and the (1-4)-th pad electrode PD1-4 may overlap the pad part PDP on the plane. The (1-1)-th pad electrode PD1-1 may overlap the first pad part PDP1, the (1-2)-th pad electrode PD1-2 may overlap the second pad part PDP2, the (1-3)-th pad electrode PD1-3 may overlap the third pad part PDP3, and the (1-4)-th pad electrode PD1-4 may overlap the fourth pad part PDP4. Each of the (1-1)-th conductive pattern CL1-1 and the (2-1)-th conductive pattern CL2-1 may overlap the first pad part PDP1. Each of the (1-2)-th conductive pattern CL1-2 and the (2-2)-th conductive pattern CL2-2 may overlap the second pad part PDP2. Each of the (1-3)-th conductive pattern CL1-3 and the (2-3)-th conductive pattern CL2-3 may overlap the third pad part PDP3. Each of the (1-4)-th conductive pattern CL1-4 and the (2-4)-th conductive pattern CL2-4 may overlap the fourth pad part PDP4.

The first pad electrode PD1 may further include a plurality of auxiliary patterns PL in addition to the first conductive pattern CL1 and the second conductive pattern CL2. In FIG. 8, each of the auxiliary patterns PL is illustrated as a square shape on the plane, but is not limited thereto and may have various shapes. For example, each of the auxiliary patterns PL may have a circular shape on the plane, or each of the auxiliary patterns PL may have a polygonal shape such as a triangular shape on the plane.

The auxiliary pattern PL may include a polymer material. The auxiliary pattern PL may include an organic insulating material. The auxiliary pattern PL may include a thermosetting polymer material or a thermoplastic polymer material. The auxiliary pattern PL may include, for example, polyimide.

The auxiliary patterns PL may be provided in plurality and may be arranged along one direction. The auxiliary patterns PL may be arranged to be shifted by a distance (e.g., a set or predetermined distance) in at least one of the first direction DR1 or the second direction DR2, for example, as illustrated in FIG. 8. The auxiliary patterns PL may be arranged in parallel along the second direction DR2. In addition, the auxiliary patterns PL may be arranged to be shifted by a distance (e.g., a set or predetermined distance) in the second direction DR2 or in an opposite direction of the second direction DR2 with respect to the first direction DR1. For example, the auxiliary patterns PL may be arranged along a first diagonal direction DR-a.

The auxiliary pattern PL may include a first auxiliary pattern PL1 and a second auxiliary pattern PL2. The first auxiliary pattern PL1 may be located on at least a portion of the first conductive pattern CL1. The first auxiliary pattern PL1 may be provided in plurality. The first auxiliary pattern PL1 may include a plurality of first unit auxiliary patterns of which at least some are located on the first conductive pattern CL1. The second auxiliary pattern PL2 may not overlap the first conductive pattern CL1 on the plane. The second auxiliary pattern PL2 may be provided in plurality. The second auxiliary pattern PL2 may include a plurality of second unit auxiliary patterns that do not overlap the first conductive pattern CL1.

The plurality of first unit auxiliary patterns included in the first auxiliary pattern PL1 may include a first sub-unit auxiliary pattern that completely overlaps the first conductive pattern CL1. The first sub-unit auxiliary pattern may correspond to a (1-1)-th auxiliary pattern PL1-1 illustrated in FIG. 9A. The first sub-unit auxiliary pattern may correspond to each of a (1-a)-th auxiliary pattern PL1-a and a (1-b)-th auxiliary pattern PL1-b illustrated in FIG. 9B. The (1-1)-th auxiliary pattern PL1-1 may be entirely located on a (1-1)-th conductive pattern CL1-1 to entirely overlap the (1-1)-th conductive pattern CL1-1.

The plurality of first unit auxiliary patterns included in the first auxiliary pattern PL1 may include a second sub-unit auxiliary pattern of which some overlap the first conductive pattern CL1 on the plane, and remaining some do not overlap the first conductive pattern CL1. The second sub-unit auxiliary pattern may correspond to the (1-2)-th auxiliary pattern PL1-2 illustrated in FIG. 9A. Some of the patterns of the (1-2)-th auxiliary pattern PL1-2 may be located on the (1-2)-th conductive pattern CL1-2, and the remaining some may not overlap the (1-2)-th conductive pattern CL1-2.

The second conductive pattern CL2 may cover at least a portion of an upper portion of the first auxiliary pattern PL1. The second conductive pattern CL2 may entirely cover an upper portion of at least a portion of the first auxiliary patterns PL1. The second conductive pattern CL2 may entirely cover an upper portion of the first sub-unit auxiliary pattern of the first auxiliary patterns PL1. As illustrated in FIG. 9A, the (2-1)-th conductive pattern CL2-1 may entirely cover the upper portion of the (1-1)-th auxiliary pattern PL1-1 corresponding to the first sub-unit auxiliary pattern. The second conductive pattern CL2 may cover only a portion of the first auxiliary pattern PL1 and expose a remaining portion of the first auxiliary pattern PL1. The second conductive pattern CL2 may cover only a portion of the second sub-unit auxiliary pattern of the first auxiliary patterns PL1 and expose a remaining portion of the second sub-unit auxiliary pattern. As illustrated in FIG. 9A, the (2-2)-th conductive pattern CL2-2 may cover a portion of an upper portion of the (1-2)-th auxiliary pattern PL1-2 corresponding to the second sub-unit auxiliary pattern and expose a remaining portion of the upper portion.

The second conductive pattern CL2 may not overlap at least some of the second auxiliary patterns PL2 on the plane. As illustrated in FIG. 9A, the second conductive pattern CL2 may not overlap the (2-1) auxiliary pattern PL2-1 located between the (2-1)-th conductive pattern CL2-1 and the (2-2)-th conductive pattern CL2-2 on the plane. The second conductive pattern CL2 may not overlap the (2-2)-th auxiliary pattern PL2-2 located adjacent to the (2-2)-th conductive pattern CL2-2. However, unlike that is shown, a portion of the (2-2)-th conductive pattern CL2-2 may overlap a portion of the (2-2)-th auxiliary pattern PL2-2 on the plane.

The second conductive patterns CL2 provided in plurality may extend along the first direction DR1 and be spaced apart from each other along the second direction DR2. A spaced portion SP may be provided between second conductive patterns CL2 spaced from each other along the second direction DR2. At least a portion of the second auxiliary pattern PL2 may be located in the spaced portion SP provided between the second conductive patterns CL2. The second auxiliary pattern PL2 may include a (2-a)-th auxiliary pattern PL2-a located in the spaced portion SP.

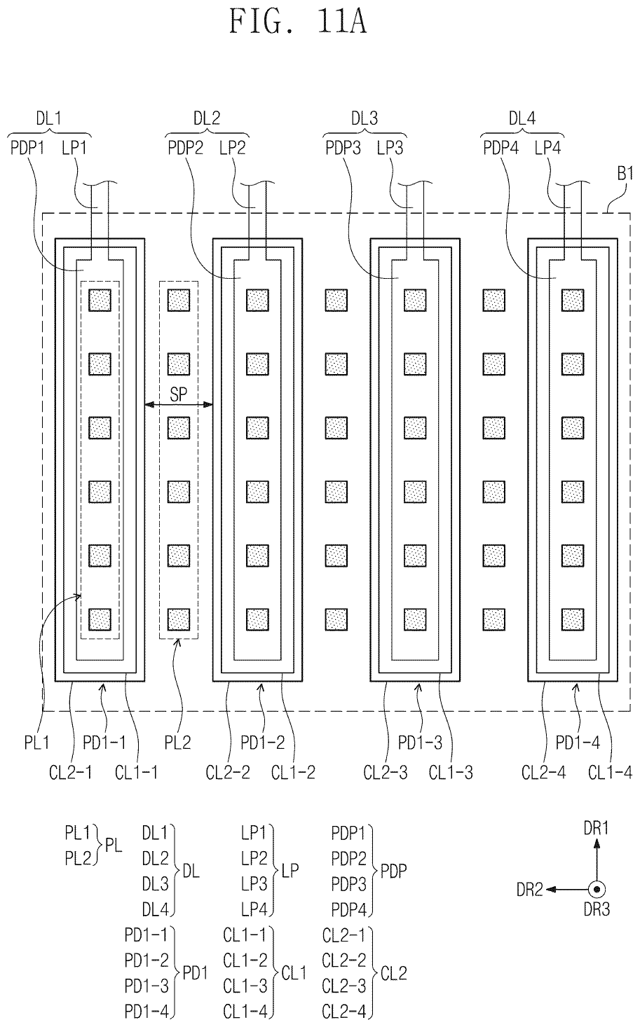

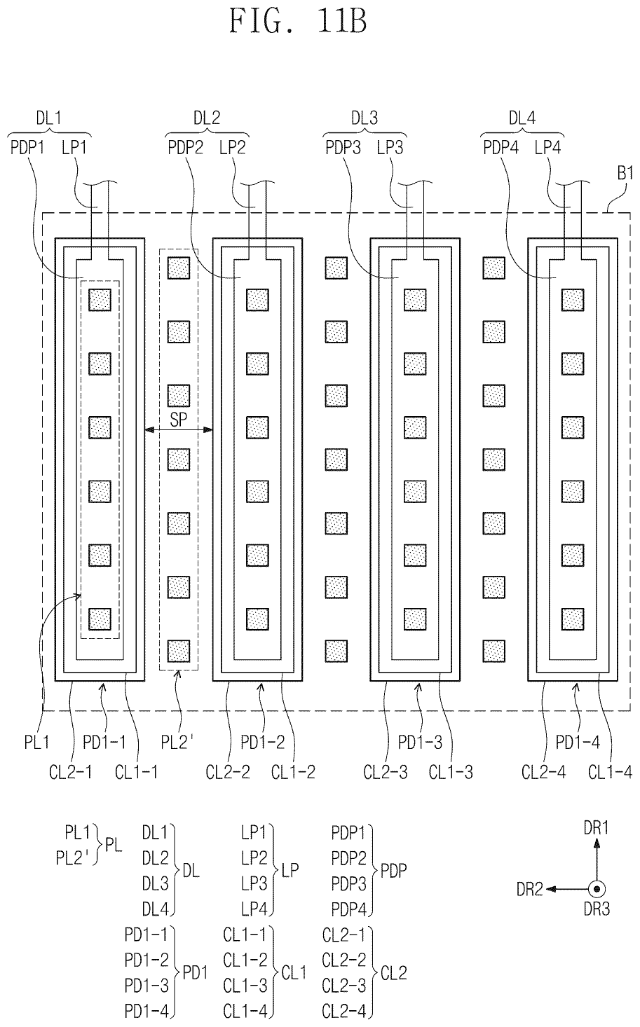

The second auxiliary pattern PL2 may include a (2-b)-th auxiliary pattern PL2-b that does not overlap the spaced portion SP. The (2-b)-th auxiliary pattern PL2-b may be located at a portion other than a portion between the second conductive patterns CL2. The (2-b)-th auxiliary pattern PL2-b may be located, for example, corresponding to a non-pad area NPD (see FIG. 11A) of the first pad areas PA1 (see FIG. 11A).

Referring to FIGS. 9A and 9B, the display panel according to some embodiments may include a substrate SUB, a barrier layer BRL, a buffer layer BFL, and a first insulating layer INS1, and the same description as those of the substrate SUB, the barrier layer BRL, the buffer layer BFL, and the first insulating layer INS1 described above with respect to FIG. 5 may be applied.

The pad part PDP may be located on the first insulating layer INS1. The pad part PDP may contain the same material as the gate G of FIG. 5 and may be formed through the same process.

An insulating pattern INS-P may be located on the pad part PDP. The insulating pattern INS-P may cover at least a portion of the pad part PDP. The insulating pattern INS-P may include, for example, at least a portion of the same material as the second insulating layer INS2, the third insulating layer INS3, and the fourth insulating layer INS4 of FIG. 5 and may be formed through the same process.

A first conductive pattern CL1 may be located on the insulating pattern INS-P. The first conductive pattern CL1 may be located directly on the insulating pattern INS-P. At least some of the first auxiliary patterns PL1 may be located on the first conductive pattern CL1. At least some of the first auxiliary patterns PL1 may be located directly on the first conductive pattern CL1. Some of the first auxiliary patterns PL1, which are not located on the first conductive pattern CL1, may be located on the insulating pattern INS-P.

A contact hole INS-OP may be provided in the insulating pattern INS-P, and at least a portion of the first conductive pattern CL1 may be located inside the contact hole INS-OP. The first conductive pattern CL1 may be in contact with the pad part PDP located at a lower side thereof through the contact hole INS-OP.

At least a portion of the second conductive pattern CL2 may be located on the first auxiliary pattern PL1 to cover at least a portion of the first auxiliary pattern PL1. At least some of the second conductive patterns CL2 may be located directly on the first auxiliary pattern PL1. Some of the second conductive patterns CL2, which are not located on the first auxiliary pattern PL1, may be located on the first conductive pattern CL1. The second conductive pattern CL2 may be in contact with some of the first conductive patterns CL1 and may be electrically connected to the first conductive pattern CL1.

Each of the first conductive pattern CL1 and the second conductive pattern CL2 may include the same material as some of the components included in the above-described pixel PX (see FIG. 5). Each of the first conductive pattern CL1 and the second conductive pattern CL2 may include at least a portion of the same material as at least some of the conductive layers such as the connection electrode CNE (see FIG. 5) included in the pixel PX (see FIG. 5). The first conductive pattern CL1 may include the same material as the first connection electrode CNE1 (see FIG. 5). The second conductive pattern CL2 may include the same material as the second connection electrode CNE2 (see FIG. 5).

The second auxiliary pattern PL2 may not overlap the first conductive pattern CL1 on the plane. At least some of the second auxiliary patterns PL2 may be located corresponding to a portion at which the insulating pattern INS-P is not located. At least some of the second auxiliary patterns PL2 may be directly located on the first insulating layer INS1. Some of the second auxiliary patterns PL2 may be located on some of the insulating patterns INS-P.

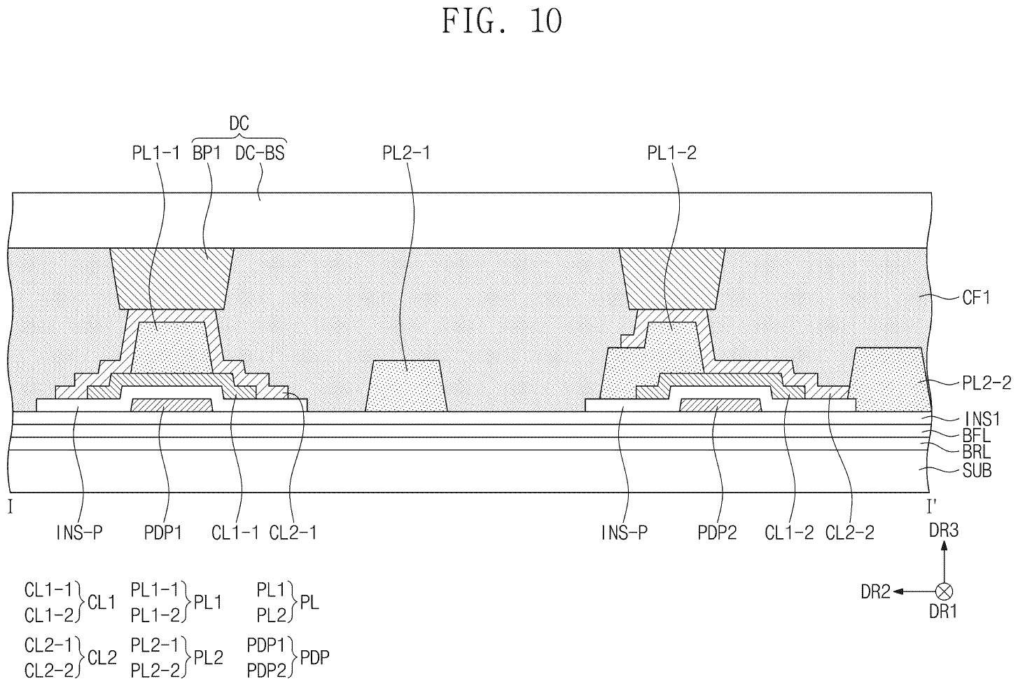

FIG. 10 is a cross-sectional view illustrating a portion of the display device according to some embodiments of the present disclosure. FIG. 10 illustrates a cross-section of the display device, which corresponds to the cross-section of the display panel illustrated in FIG. 9A. That is, in FIG. 10, in the cross-section corresponding to a cutting line I-I′ illustrated in FIG. 8, a shape of the cross-section in which the first pads of the display panel and the first bump electrodes of the driver are bonded is illustrated.

Referring to FIGS. 8 and 10, the driver DC may include a driver-integrated circuit DC-BS and first bump electrodes BP1 located below the driver-integrated circuit DC-BS. The first bump electrodes BP1 of the driver DC may be electrically connected to corresponding pad electrodes of the first pad electrodes PD1 of the display panel. The first bump electrodes BP1 may be in contact with the second conductive pattern CL2 of the first pad electrodes PD1 and may be electrically connected to the second conductive pattern CL2. The first bump electrodes BP1 may be in contact with a portion of the second conductive pattern CL2, which is located on the first auxiliary pattern PL1. Some of the first bump electrodes BP1 may be in contact with a portion of the (2-1)-th conductive patterns CL2-1, which is located on the (1-1)-th auxiliary pattern PL1-1. Some of the first bump electrodes BP1 may be in contact with a portion of the (2-2)-th conductive patterns CL2-2, which is located on the (1-2)-th auxiliary pattern PL1-2.

The driver DC may be bonded to the first pad area PA1 through the first adhesion layer CF1. The first adhesion layer CF1 may include a non-conductive film. The first adhesion layer CF1 may not include conductive particles such as conductive balls and may be made of a curable polymer material.

In the display device according to some embodiments, the pad electrode may include a first conductive pattern and a second conductive pattern and may further include an auxiliary pattern located on the first conductive pattern and partially covered by the second conductive pattern. Thus, because a portion of the second conductive pattern located at the upper side is in contact with the bump electrodes of the driver by the auxiliary pattern having the protruding shape, the display panel and the electrodes of the driver may be connected to each other through the non-conductive film without the conductive particles such as the conductive balls. As a result, even if an alignment of the display panel and the driver is misaligned, short circuit due to the conductive particles such as the conductive balls may not occur, and thus, electrical connection characteristics between the pad electrode and the bump electrode may be relatively improved.

In the display device according to some embodiments, the auxiliary pattern may not be only patterned on the first conductive pattern, but a portion of the auxiliary pattern may also be located at a portion at which the first conductive pattern is not located. That is, in the display device according to some embodiments, the auxiliary pattern may include a first auxiliary pattern located on at least a portion of the first conductive pattern, and a second auxiliary pattern that does not overlap the first conductive pattern. According to some embodiments, because the auxiliary pattern is provided to have a constant arrangement regardless of the arrangement position of the first conductive pattern during the process of manufacturing the display device, the auxiliary pattern may include the first auxiliary pattern and the second auxiliary pattern, and thus, the auxiliary pattern may be formed without a separate mask process, a connection structure between the display panel and the electrodes of the driver, from which the conductive ball is omitted, may be formed through a simplified process.

FIGS. 11A and 11B are enlarged plan views illustrating a portion of the first pad electrodes according to some embodiments of the present disclosure. FIGS. 11A and 11B illustrate embodiments in which the arrangement of the auxiliary patterns PL is different from that illustrated in FIG. 8.

Referring to FIG. 11A, unlike the embodiments illustrated in FIG. 8, the auxiliary patterns PL may be arranged in parallel along the first direction DR1 which is an extension direction of the first pad electrodes PD1 and may be arranged in parallel along the second direction DR2 which is a spaced direction of the first pad electrodes PD1. As illustrated in FIG. 11A, the auxiliary patterns PL may be arranged side by side at a constant interval along each of the first direction DR1 and the second direction DR2. The auxiliary patterns PL may include a plurality of first auxiliary patterns PL1 and a plurality of second auxiliary patterns PL2, and each of the plurality of first auxiliary patterns PL1 and the plurality of second auxiliary patterns PL2 may be arranged side by side at a constant interval along each of the first direction DR1 and the second direction DR2.

Referring to FIG. 11B, unlike that illustrated in FIG. 11A, the auxiliary patterns PL may be arranged in parallel along the first direction DR1, which is the extension direction of the first pad electrodes PD1, but may not be arranged in parallel along the second direction DR2, which is the spaced direction of the first pad electrodes PD1. The auxiliary patterns PL may include a plurality of first auxiliary patterns PL1 and a plurality of second auxiliary patterns PL2′, and each of the plurality of first auxiliary patterns PL1 and the plurality of second auxiliary patterns PL2′ may be arranged side by side along the first direction DR1. The adjacent first auxiliary patterns PL1 and second auxiliary patterns PL2′ may not be arranged in parallel along the second direction DR2, but may be arranged to be shifted by a distance (e.g., a set or predetermined distance). The first auxiliary patterns PL1 and second auxiliary patterns PL2′, which are adjacent to each other, may be arranged in a zigzag shape with a diagonal direction as the progressing direction.

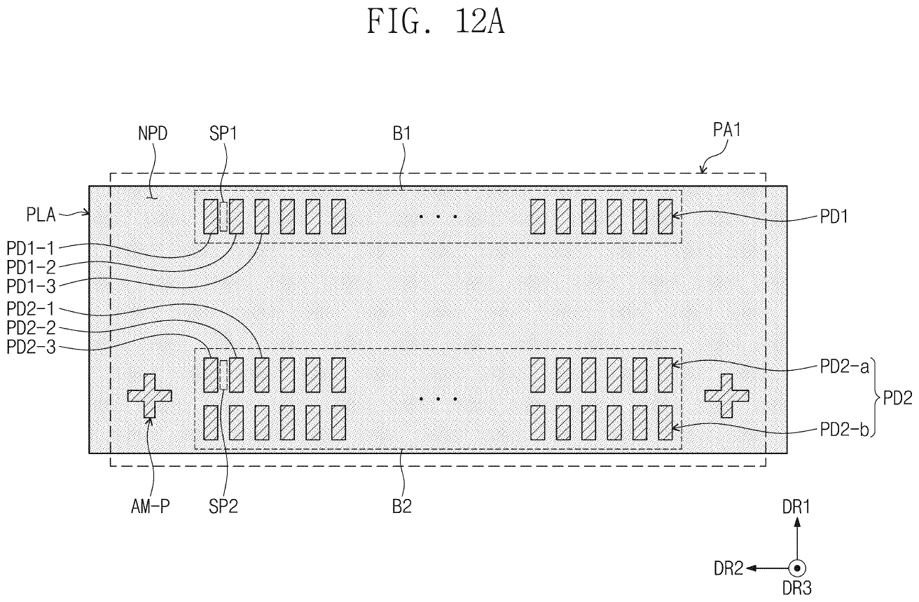

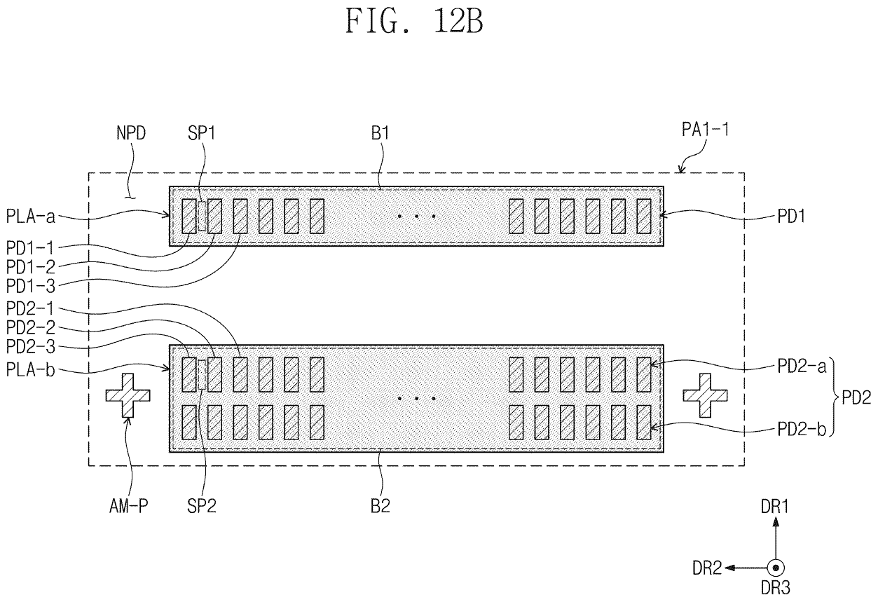

FIGS. 12A and 12B are enlarged plan views of the first pad area according to some embodiments of the present disclosure. In FIG. 12A and FIG. 12B, a plurality of first pad electrodes PD1 and second pad electrodes PD2 located on the first pad areas PA1 and PA1-1 and auxiliary pattern areas PLA, PLA-a, and PLA-b on which the auxiliary patterns PL described above in FIG. 8 are located are illustrated.

Referring to FIGS. 8 and 12a together, the display panel may further include an alignment mark AM-P located on the first pad area PA1. The alignment mark AM-P may overlap at least one of the first pad electrodes PD1 or the second pad electrodes PD2 in one direction. The alignment mark AM-P may, for example, overlap the second pad electrodes PD2 in the first direction DR1. The alignment mark AM-P may be applied as an identification mark to identify a position of the display panel DP (see FIG. 7) in the process of bonding the driver DC (see FIG. 7) and the display panel DP (see FIG. 7) or to align the driver DC (see FIG. 7) and the display panel DP (see FIG. 7) with each other. In FIG. 12A, the alignment mark AM-P is illustrated as including a cross shape and a square shape as an example, but is not limited thereto, and the alignment mark AM-P may be provided in various shapes as long as it is for the purpose of aligning each configuration.

In the display panel according to some embodiments, the auxiliary pattern area PLA on which the auxiliary patterns PL are located may overlap at least the pad electrodes PD1 and PD2. The auxiliary pattern area PLA may overlap the first area B1 on which the first pad electrodes PD1 are located and the second area B2 on which the second pad electrodes PD2 are located.

The first pad electrodes PD1 may be provided in plurality. A first spaced portion SP1 may be provided between the plurality of first pad electrodes PD1-1, PD1-2, and PD1-3, and an auxiliary pattern area PLA may overlap the first spaced portion SP1. The second pad electrodes PD2 may be provided in plurality. A second spaced portion SP2 may be provided between the plurality of second pad electrodes PD2-1, PD2-2, and PD2-3, and the auxiliary pattern area PLA may overlap the second spaced portion SP2.

The auxiliary pattern area PLA may overlap not only the first area B1 and the second area B2 on which the pad electrodes PD1 and PD2 are arranged, but also the non-pad area NPD. The non-pad area NPD may be an area on which the pad electrodes are not provided. According to some embodiments, the above-described (2-a)-th auxiliary pattern PL2-a (see FIG. 8) may be located on each of the first spaced portion SP1 and the second spaced portion SP2, and the above-described (2-b)-th auxiliary pattern PD2-b (see FIG. 8) may be located on the non-pad area NPD.

Referring to FIG. 12B together, unlike FIG. 12A, the auxiliary pattern areas PLA-a and PLA-b) on the first pad area PA1-1 may overlap the first area B1 and the second area B2, on which the pad electrodes PD1 and PD2 are located, and may not overlap the non-pad area NPD. That is, separate auxiliary patterns may not be provided on the non-pad area NPD. In the display panel according to some embodiments, the above-described (2-b)-th auxiliary pattern PD2-b (see FIG. 8) may be omitted. The auxiliary pattern areas PLA-a and PLA-b may include a first auxiliary pattern area PLA-a overlapping the first area B1, and a second auxiliary pattern area PLA-b overlapping the second area B2. The first auxiliary pattern area PLA-a and the second auxiliary pattern area PLA-b may be spaced apart from each other along the first direction DR1.

Hereinafter, a method for manufacturing a display device according to some embodiments of the present disclosure will be described.

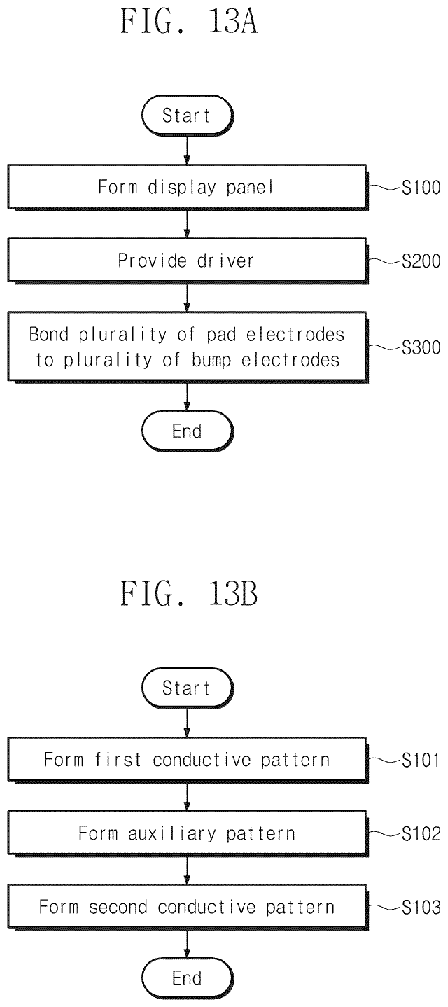

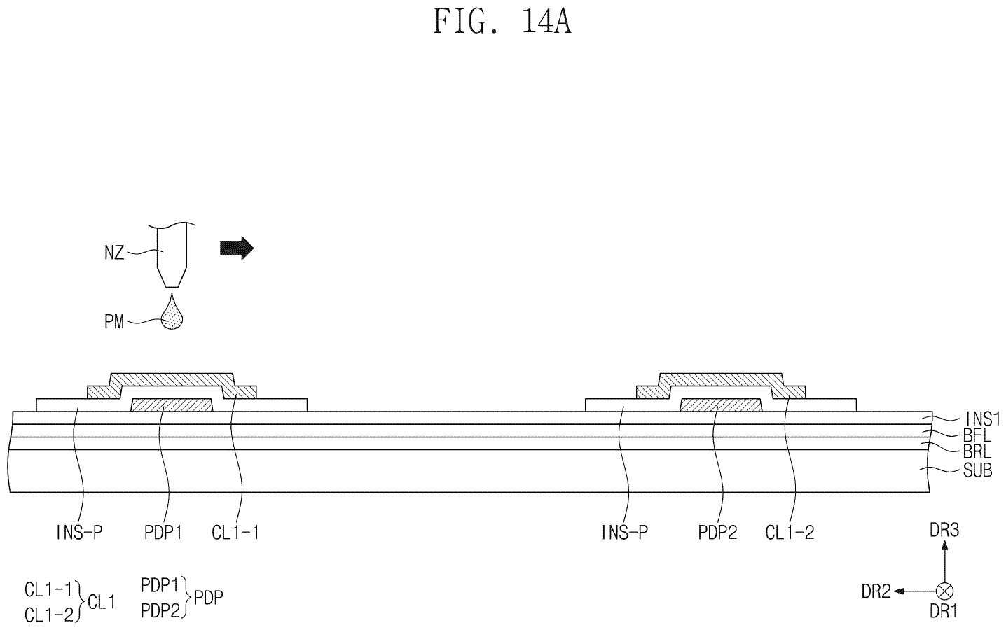

FIG. 13A is a flowchart illustrating a method for manufacturing a display device according to some embodiments of the present disclosure. Although FIG. 13A illustrates various operations in a method for manufacturing a display device, embodiments according to the present disclosure are not limited thereto, and according to various embodiments, the method may include additional operations or fewer operations, or the order of operations may vary, unless otherwise stated or implied, without departing from the spirit and scope of embodiments according to the present disclosure.

FIG. 13B is a flowchart illustrating some processes in the method for manufacturing the display device according to some embodiments of the present disclosure. Although FIG. 13B illustrates various operations in a method for manufacturing a display device, embodiments according to the present disclosure are not limited thereto, and according to various embodiments, the method may include additional operations or fewer operations, or the order of operations may vary, unless otherwise stated or implied, without departing from the spirit and scope of embodiments according to the present disclosure.

In FIG. 13B, each process included in a process of forming a plurality of pad electrodes in an operation (S100) of forming a display panel in the method for manufacturing the display device according to some embodiments is illustrated. Referring to FIG. 13A, a method for manufacturing a display device

according to some embodiments may include a process (S100) of forming a display panel including a display area on which pixels are located and a non-display area on which a plurality of pad electrodes are located, a process (S200) of providing a driver including a plurality of bump electrodes, each of which is arranged to correspond to respective ones of each of the plurality of pad electrodes on the display panel, and a process (S300) of interposing a first adhesion layer between the display panel and the driver to bond the plurality of pad electrodes to the plurality of bump electrodes. The process (S100) of forming the display panel may include a process of forming a plurality of pad electrodes on the non-display area.

Referring to FIG. 13B, the process of forming the plurality of pad electrodes may include a process (S101) of forming a first conductive pattern by providing a conductive material on the non-display area, a process (S102) of forming an auxiliary pattern to overlap at least a portion of the first conductive pattern, and a process (S103) of forming a second conductive pattern by providing a conductive material to cover at least a portion of the auxiliary pattern.

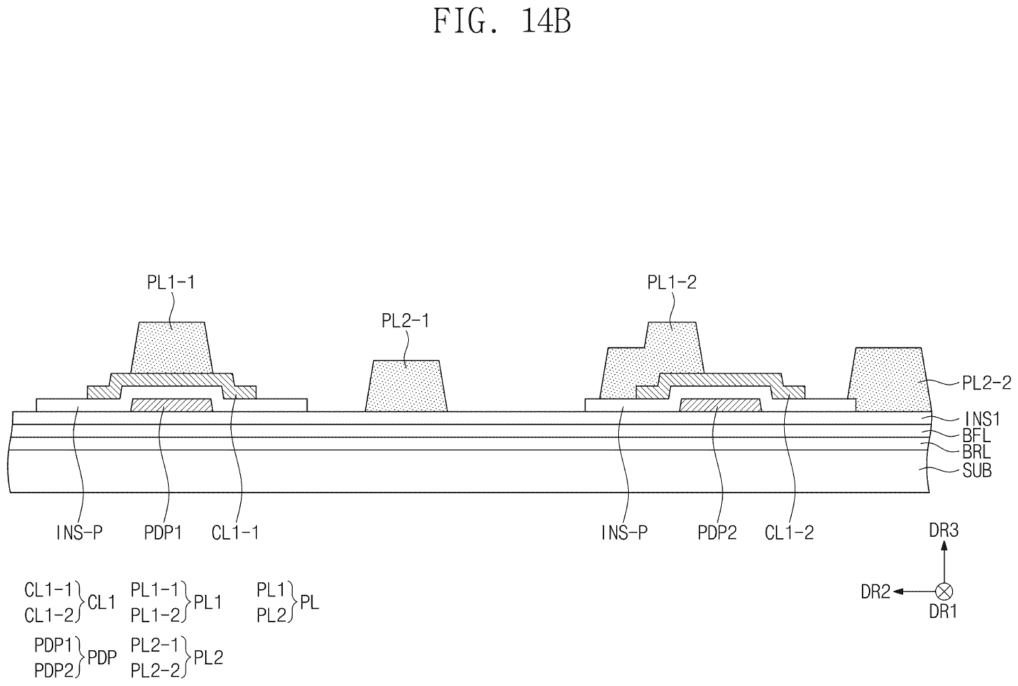

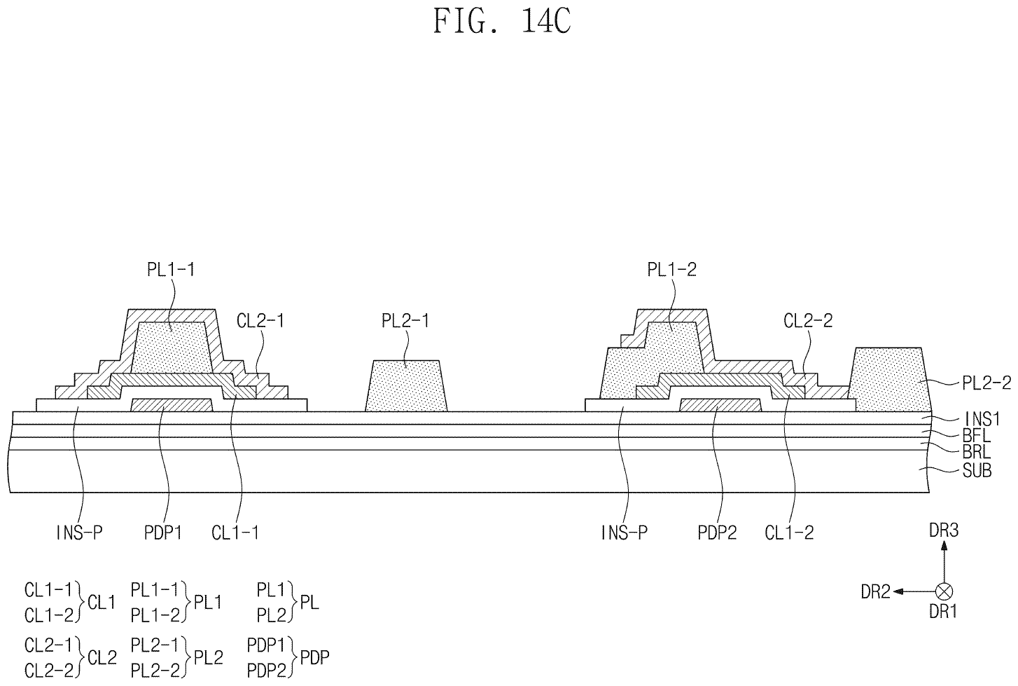

FIGS. 14A to 14C are cross-sectional views illustrating some processes in the method for manufacturing the display device according to some embodiments of the present disclosure; and In each of FIGS. 14A to 14C, a cross-section corresponding to FIG. 9A is illustrated in some processes in the process of forming the plurality of pad electrodes.

Referring to FIG. 13B and FIG. 14A together, the process of forming the plurality of pad electrodes includes a process (S101) of providing the conductive material to form a first conductive pattern CL1. The first conductive pattern CL1 may be formed to correspond to at least the pad part PDP. The first conductive pattern CL1 may be formed through a conductive metal. The first conductive pattern CL1 may include a (1-1)-th conductive pattern CL1-1 and a (1-2)-th conductive pattern CL1-2, which are spaced apart from each other along the second direction DR2. The (1-1)-th conductive pattern CL1-1 may be formed to overlap the first pad part PDP1, and the (1-2)-th conductive pattern CL1-2 may be formed to overlap the second pad part PDP2.

Referring to FIG. 13B, FIG. 14A, and FIG. 14B together, the process of forming the plurality of pad electrodes may include a process (S102) of forming an auxiliary pattern PL by providing a polymer material. The auxiliary pattern PL may be formed to overlap at least partly the first conductive pattern CL1. The auxiliary pattern PL may include a first auxiliary pattern PL1 that overlaps at least a portion of the first conductive pattern CL1. The auxiliary pattern PL may include a second auxiliary pattern PL2 that does not overlap the first conductive pattern CL1.

The process (S102) of forming the auxiliary pattern PL may be performed through a printing process. The process of forming the auxiliary pattern PL may be performed through an inkjet printing process by providing a polymer material PM through a nozzle NZ, for example, as illustrated in FIG. 14A. The polymer material PM supplied through the nozzle NZ may be cured to form the auxiliary pattern PL. According to some embodiments, the process (S102) of forming the auxiliary pattern PL may be performed through the printing process, and thus, a plurality of auxiliary patterns PL spaced apart from each other at a constant interval and with a an arrangement (e.g., a set or predetermined arrangement) may be formed without a separate mask process. The process of forming the auxiliary patterns PL may include a process of forming a first auxiliary pattern PL1 and a process of forming a second auxiliary pattern PL2. The first auxiliary pattern PL1 may include a first auxiliary pattern PL1-1 that entirely overlaps the first conductive pattern CL1-1. The first auxiliary pattern PL1 may include a (1-2)-th auxiliary pattern PL1-2 that partially overlaps the (1-2)-th conductive pattern CL1-2.

Referring to FIGS. 13B, 14B, and 14C together, the process of forming the plurality of pad electrodes may include a process (S103) of providing a conductive material to form a second conductive pattern CL2.

The second conductive pattern CL2 may be formed to correspond to at least the first conductive pattern CL1. The second conductive pattern CL2 may be formed through a conductive metal. The second conductive pattern CL2 may include a (2-1)-th conductive pattern CL2-1 and a (2-2)-th conductive pattern CL2-2, which are spaced apart from each other along the second direction DR2. The 2-1 conductive pattern CL2-1 may be formed to overlap the (1-1)-th conductive pattern CL1-1, and the (2-2)-th conductive pattern CL2-2 may be formed to overlap the 1-2 conductive pattern CL1-2.

The second conductive pattern CL2 may be formed to cover at least a portion of an upper portion of the first auxiliary pattern PL1. The second conductive pattern CL2 may be formed to entirely cover an upper portion of at least a portion of the first auxiliary patterns PL1. As illustrated in FIG. 14C, the 2-1 conductive pattern CL2-1 may be formed to entirely cover an upper portion of the (1-1)-th auxiliary pattern PL1-1 corresponding to a first sub-unit auxiliary pattern. The second conductive pattern CL2 may be formed to cover only a portion of some of the patterns of the first auxiliary pattern PL1 and expose a remaining portion. As illustrated in FIG. 14C, the (2-2)-th conductive pattern CL2-2 may be formed to cover an upper portion of the (1-2)-th auxiliary pattern PL1-2 corresponding to a second sub-unit auxiliary pattern and expose a remaining portion.

The second conductive pattern CL2 may be formed so as not to overlap at least a portion of the second auxiliary pattern PL2 on the plane. As illustrated in FIG. 14C, the second conductive pattern CL2 may not overlap the (2-1) auxiliary pattern PL2-1 located between the (2-1)-th conductive pattern CL2-1 and the (2-2)-th conductive pattern CL2-2 on the plane. The second conductive pattern CL2 may not overlap the (2-2)-th auxiliary pattern PL2-2 located adjacent to the (2-2)-th conductive pattern CL2-2. However, unlike that is shown, a portion of the (2-2)-th conductive pattern CL2-2 may overlap a portion of the (2-2)-th auxiliary pattern PL2-2 on the plane.

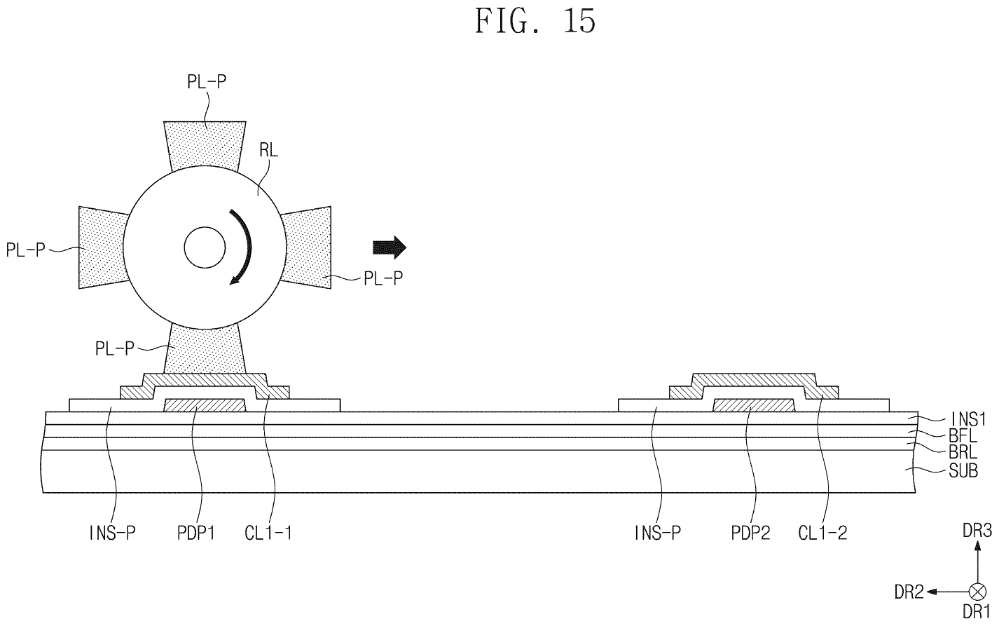

FIG. 15 is a cross-sectional view illustrating some processes in the method for manufacturing the display device according to some embodiments of the present disclosure. FIG. 15 illustrates a cross-section of some process in a process of forming a plurality of pad electrodes according to some embodiments in the cross-section corresponding to FIG. 14A.

Referring to FIG. 13B and FIG. 15, unlike that illustrated in FIG. 14A, a process (S102) of forming an auxiliary pattern PL may be performed through an offset printing process rather than the inkjet printing process. The operation (S102) of forming the auxiliary pattern PL may include a process of forming a preliminary auxiliary pattern PL-P on a roller RL. The auxiliary pattern PL-P formed on the roller RL may be provided to have an interval (e.g., a set or predetermined interval) and arrangement according to a rotational motion of the roller RL, thereby forming an auxiliary pattern PL (see FIG. 14B).

In the display device according to some embodiments, the pad electrode may include the auxiliary pattern, which is located on the first conductive pattern, and of which a portion is covered by the second conductive pattern. In the display device according to some embodiments, because the portion of the second conductive pattern located at the upper side is in contact with the bump electrodes of the driver by the auxiliary pattern having the protruding shape, the display panel and the electrodes of the driver may be connected to each other through the non-conductive film without the conductive particles such as the conductive balls. In addition, in the display device according to some embodiments, because the auxiliary pattern is provided to have the certain arrangement regardless of the arrangement position of the first conductive pattern during the process of manufacturing the display device, the formation of the auxiliary pattern may be realized without the separate mask process.

Therefore, in the display device according to some embodiments, the connection structure between the display panel, from which the conductive ball is omitted through the simplified process, and the electrodes of the driver may be provided, and the electrical connection characteristics between the electrode pad and the bump may be relatively improved.

It will be apparent to those skilled in the art that various modifications and variations may be made in the present disclosure. Thus, it is intended that the present disclosure covers the modifications and variations of this invention provided they come within the scope of the appended claims and their equivalents.

Hence, the scope of embodiments according to the present disclosure shall be determined by the appended claims, and their equivalents.

What is claimed is:

1. A display device comprising:
a display panel comprising a display area, on which a pixel is located, and a non-display area, on which a plurality of pad electrodes are located; and
a driver on the display panel and comprising a plurality of bump electrodes, each of which is arranged to correspond to respective ones of each of the plurality pad electrodes,
wherein the plurality of pad electrodes comprise:
a first conductive pattern comprising a conductive material;
an auxiliary pattern protruding toward the bump electrodes and comprising an insulating material; and
a second conductive pattern comprising a conductive material,
wherein the auxiliary pattern comprises:
a first auxiliary pattern on at least a portion of the first conductive pattern; and
a second auxiliary pattern that does not overlap the first conductive pattern in a plan view,
wherein the second conductive pattern covers at least a portion of an upper portion of the first auxiliary pattern.

2. The display device of claim 1, wherein the first auxiliary pattern comprises a plurality of first unit auxiliary patterns on at least a portion of the first conductive pattern, and
the second auxiliary pattern comprises a plurality of second unit auxiliary patterns that do not overlap the first conductive pattern.

3. The display device of claim 2, wherein the plurality of first unit auxiliary patterns comprise a first sub-unit auxiliary pattern that entirely overlaps the first conductive pattern in the plan view.

4. The display device of claim 2, wherein the plurality of first unit auxiliary patterns comprise a second sub-unit auxiliary pattern of which a portion overlaps the first conductive pattern in the plan view, and a remaining portion does not overlap the first conductive pattern.

5. The display device of claim 2, wherein the second conductive pattern is provided in plurality,
wherein the plurality of second conductive patterns extend in a first direction and are spaced apart from each other in a second direction crossing the first direction, and
each of the plurality of first unit auxiliary patterns and the plurality of second unit auxiliary patterns are arranged side by side in the first direction and the second direction.

6. The display device of claim 2, wherein the second conductive pattern is provided in plurality,
wherein the plurality of second conductive patterns extend in a first direction and are arranged spaced apart from each other in a second direction crossing the first direction, and
each of the plurality of first unit auxiliary patterns and the plurality of second unit auxiliary patterns are arranged to be shifted by a predetermined distance in at least one of the first direction or the second direction.

7. The display device of claim 1, wherein the plurality of bump electrodes are in contact with the second conductive pattern.

8. The display device of claim 1, wherein the display panel further comprises a plurality of signal lines that are electrically connected to at least a portion of each of the plurality of pad electrodes,
wherein at least a portion of the plurality of signal lines is in contact with the first conductive pattern.

9. The display device of claim 1, wherein the auxiliary pattern comprises a polymer material.

10. The display device of claim 1, wherein the second conductive pattern is provided in plurality,
wherein the plurality of second conductive patterns extend in a first direction and are spaced apart from each other in a second direction crossing the first direction, and
a spaced portion is between the plurality of second conductive patterns.

11. The display device of claim 10, wherein the second auxiliary pattern comprises a (2-a)-th auxiliary pattern at the spaced portion.

12. The display device of claim 10, wherein the second auxiliary pattern comprises a (2-b)-th auxiliary pattern that does not overlap the spaced portion.

13. The display device of claim 1, wherein the display panel further comprises an insulating pattern below the first conductive pattern, and
the second auxiliary pattern does not overlap the insulating pattern in the plan view.

14. The display device of claim 1, wherein a portion of the second conductive pattern is in contact with the first conductive pattern.

15. The display device of claim 1, wherein the second conductive pattern is directly on at least a portion of an upper portion of the first auxiliary pattern.

16. The display device of claim 1, further comprising a first adhesion layer between the display panel and the driver,
wherein the first adhesion layer comprises a non-conductive film.

17. The display device of claim 1, wherein the pixel comprises:
a light emitting element;
a transistor electrically connected to the light emitting element and comprising a semiconductor pattern and a gate overlapping the semiconductor pattern; and
a plurality of conductive layers electrically connected to the transistor and on different layers on the transistor,
wherein each of the first conductive pattern and the second conductive pattern comprises a same material as at least one of the plurality of conductive layers.

18. A method for manufacturing a display device, the method comprising:
forming a display panel comprising a display area, on which a pixel is located, and a non-display area, on which a plurality of pad electrodes are located;
providing a driver comprising a plurality of bump electrodes arranged to respectively correspond to the plurality of pad electrodes on the display panel; and
interposing and pressing a first adhesion layer between the display panel and the driver to bond the plurality of pad electrodes to the plurality of bump electrodes,
wherein the forming of the display panel comprises forming the plurality of pad electrodes on the non-display area,
wherein the forming of the plurality of pad electrodes comprises:
providing a conductive material to the non-display area to form a first conductive pattern;
forming an auxiliary pattern to at least partially overlap the first conductive pattern; and
providing a conductive material to cover at least a portion of the auxiliary pattern, thereby forming a second conductive pattern,
wherein the forming of the auxiliary pattern is performed through a printing process.

19. The method of claim 18, wherein the forming of the auxiliary pattern comprises:
forming a first auxiliary pattern on at least a portion of the first conductive pattern; and
forming a second auxiliary pattern that does not overlap the first conductive pattern in a plan view, and
wherein the forming of the first auxiliary pattern comprises forming a plurality of first unit auxiliary patterns of which at least a portion is on the first conductive pattern, and
the forming of the second auxiliary pattern comprises forming a plurality of second unit auxiliary patterns that do not overlap the first conductive pattern.

20. An electronic device comprising:
a display panel comprising a display area, on which a pixel is located, and a non-display area, on which a plurality of pad electrodes are located;
a driver on the display panel and comprising a plurality of bump electrodes, each of which corresponds to respective ones of each of the plurality pad electrodes; and
a housing accommodate the display panel,
wherein the plurality of pad electrodes comprise:
a first conductive pattern comprising a conductive material;
an auxiliary pattern protruding toward the bump electrodes and comprising an insulating material; and
a second conductive pattern comprising a conductive material,
wherein the auxiliary pattern comprises:
a first auxiliary pattern on at least a portion of the first conductive pattern; and
a second auxiliary pattern that does not overlap the first conductive pattern in a plan view,
wherein the second conductive pattern covers at least a portion of an upper portion of the first auxiliary pattern.
